(19) United States
(12) Patent Application Publication
(10) Pub. No.: US 2026/0059989 A1
(43) Pub. Date: Feb. 26, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: KYUMIN KIM, Yongin-si (KR); SHINHYUK YANG, Yongin-si (KR); DONGHAN KANG, Yongin-si (KR)

(21) Appl. No.: 19/259,187

(22) Filed: Jul. 3, 2025

(30) Foreign Application Priority Data
Aug. 22, 2024 (KR) 10-2024-0112546

(51) Int. Cl. H10K 59/80; H10K 59/12

(52) U.S. Cl. CPC H10K 59/8791; H10K 59/1201; H10K 59/80517

(57) ABSTRACT

A display device includes a substrate including a first pixel area and a second pixel area adjacent to the first pixel area, a first pixel electrode layer disposed in the first pixel area on the substrate, a second pixel electrode layer disposed in the second pixel area on the substrate, a first resonant layer disposed on the first pixel electrode layer and including an inorganic material, a second resonant layer disposed on the second pixel electrode layer and including an inorganic material, a first conductive layer disposed on the first resonant layer, a second conductive layer disposed on the second resonant layer, wherein a height of an upper surface of the second conductive layer is different from a height of an upper surface of the first conductive layer with respect to the substrate, and a light emitting layer disposed on the first conductive layer and the second conductive layer.

This application claims priority to Korean Patent Application No. 10-2024-0112546, filed on Aug. 22, 2024, and all the benefits accruing therefrom under 35 U.S.C. § 119, the content of which in its entirety is herein incorporated by reference.

### BACKGROUND

### 1. Field

The present disclosure relates to a display device, a method of manufacturing the display device, and an electronic device including the display device. More specifically, the present disclosure relates to a display device that provides visual information, the method of manufacturing the display device, and the electronic device including the display device.

### 2. Description of the Related Art

As a utilization of display devices becomes more diverse, interest in large display devices such as, for example, smartphones, large televisions, and vehicle displays continues. Recently, intensive research on enlarging display devices is being conducted, and brightness uniformity and brightness enhancement technologies are being developed.

In particular, a technology that amplifies the intensity of emitted light using constructive interference is being studied as one of the technologies for brightness enhancement.

### SUMMARY

One purpose of the present disclosure is to provide an anti-reflection layer that prevents reflection of light.

Another purpose of the present disclosure is to provide a display device including the anti-reflection layer.

Still another purpose of the present disclosure is to provide an electronic device including the display device.

A display device according to an embodiment of the present disclosure includes a substrate including a first pixel area and a second pixel area adjacent to the first pixel area, a first pixel electrode layer disposed in the first pixel area on the substrate, a second pixel electrode layer disposed in the second pixel area on the substrate, a first resonant layer disposed on the first pixel electrode layer and including an inorganic material, a second resonant layer disposed on the second pixel electrode layer and including the inorganic material, a first conductive layer disposed on the first resonant layer, a second conductive layer disposed on the second resonant layer, wherein a height of an upper surface of the second conductive layer is different from a height of an upper surface of the first conductive layer with respect to the substrate, and a light emitting layer disposed on the first conductive layer and the second conductive layer.

In an embodiment, each of the first resonant layer and the second resonant layer may include at least one selected from a group including silicon nitride and silicon oxide.

In an embodiment, a thickness of the first resonant layer and a thickness of the second resonant layer may be equal to one another.

In an embodiment, each of the first resonant layer and the second resonant layer may include a transparent material.

In an embodiment, the first pixel electrode layer may include a first lower electrode layer, a first reflective electrode layer, and a first upper electrode layer sequentially disposed on the substrate, and the second pixel electrode layer may include a second lower electrode layer, a second reflective electrode layer, and a second upper electrode layer sequentially disposed on the substrate.

In an embodiment, the first upper electrode layer of the first pixel electrode layer may be electrically connected to the first conductive layer, and the second upper electrode layer of the second pixel electrode layer may be electrically connected to the second conductive layer.

In an embodiment, the first lower electrode layer, the first upper electrode layer, and the first conductive layer may include a same material.

In an embodiment, a height of an upper surface of each of the first pixel electrode layer and a height of an upper surface of the second pixel electrode layer may be equal with respect to the substrate.

In an embodiment, a thickness of the first pixel electrode layer and a thickness of the second pixel electrode layer may be different from each other.

In an embodiment, the light emitting layer may include a light emitting material that emits white light or blue light.

In an embodiment, the display device may further include a common electrode disposed on the light emitting layer, wherein the common electrode is a plate electrode.

In an embodiment, the display device may further include a first color conversion layer disposed on the common electrode, overlapping the first pixel electrode layer in a plan view, and converting light emitted from the light emitting layer into light of a first color and a second color conversion layer disposed on the common electrode, overlapping the second pixel electrode layer in a plan view, and converting the light emitted from the light emitting layer into light of a second color different from the first color.

In an embodiment, a resonance distance between the common electrode and a first reflective electrode layer included in the first pixel electrode layer may satisfy a following Equation 1:

L=(λ/2)×N,
wherein L is the resonance distance, λ is a median value of a wavelength of the first color, and N is a natural number.

In an embodiment, the substrate may further include a third pixel area adjacent to the second pixel area and the display device may further include a third pixel electrode layer disposed in the third pixel area on the substrate

In an embodiment, the third pixel electrode layer may include a third lower electrode layer, a third reflective electrode layer, and a third upper electrode layer sequentially disposed on the substrate, and the third upper electrode layer may be in direct contact with the light emitting layer.

A method of manufacturing a display device according to an embodiment of the present disclosure includes forming a preliminary lower electrode layer, a preliminary reflective electrode layer, a preliminary upper electrode layer, a preliminary resonant layer, and a first preliminary conductive layer sequentially on a substrate including a first pixel area and a second pixel area adjacent to the first pixel area, forming a first photoresist in the first pixel area on the first preliminary conductive layer, forming a second photoresist in the second pixel area on the first preliminary conductive layer, wherein the second photoresist has an upper surface at a same height as an upper surface of the first photoresist with respect to an upper surface of the substrate, removing a portion of the second photoresist using a halftone mask, etching the first preliminary conductive layer and the preliminary resonant layer through a first etching process, removing the second photoresist, etching the first preliminary conductive layer and the preliminary upper electrode layer through a second etching process, and forming a first pixel electrode layer, a first resonant layer, and a first conductive layer in the first pixel area and at a same time forming a second pixel electrode layer, a second resonant layer, and a second conductive layer in the second pixel area, by patterning the preliminary lower electrode layer, the preliminary reflective electrode layer, and the preliminary upper electrode layer.

In an embodiment, the first etching process may be performed using a first gas including hydrogen chloride (HCl).

In an embodiment, the second etching process may be performed using a second gas including acetone (CH₃COCH₃), argon (Ar), and oxygen (O).

In an embodiment, in the second etching process, an etching selectivity of the first preliminary conductive layer with respect to the second gas is greater than an etching selectivity of the preliminary resonant layer with respect to the second gas.

In an embodiment, the method may further include forming a light emitting layer using an open mask on the first pixel electrode layer and the second pixel electrode layer.

An electronic device according to an embodiment of the present disclosure includes device a display device and a processor configured to drive the display device, wherein the display device includes a substrate including a first pixel area and a second pixel area adjacent to the first pixel area, a first pixel electrode layer disposed in the first pixel area on the substrate, a second pixel electrode layer disposed in the second pixel area on the substrate, a first resonant layer disposed on the first pixel electrode layer and including an inorganic material, a second resonant layer disposed on the second pixel electrode layer and including an inorganic material, a first conductive layer disposed on the first resonant layer, a second conductive layer disposed on the second resonant layer, wherein a height of an upper surface of the second conductive layer is different from a height of an upper surface of the first conductive layer with respect to the substrate, and a light emitting layer disposed on the first conductive layer and the second conductive layer.

A display device according to an embodiment of the present disclosure may include a substrate including a first pixel area and a second pixel area adjacent to the first pixel area, a first pixel electrode layer disposed in the first pixel area on the substrate, a second pixel electrode layer disposed in the second pixel area on the substrate, a first resonant layer disposed on the first pixel electrode layer and including an inorganic material, a second resonant layer disposed on the second pixel electrode layer and including an inorganic material, a first conductive layer disposed on the first resonant layer, a second conductive layer disposed on the second resonant layer and a height of an upper surface of the second conductive layer is different from a height of an upper surface of the first conductive layer with respect to the substrate, and a light emitting layer disposed on the first conductive layer and the second conductive layer.

Accordingly, since the first and second conductive layers having different respective thicknesses are respectively disposed on the first and second pixel electrode layers, a distance between the common electrode and the first pixel electrode layer may be different from a distance between the common electrode and the second pixel electrode layer. Accordingly, a wavelength band that is constructively interfered between the first pixel electrode layer and the common electrode and a wavelength band that is constructively interfered between the second pixel electrode layer and the common electrode may be different. As a result, a range of the wavelength band that is constructively interfered may be selected for each pixel, and by utilizing this, a light of the wavelength band of a preset color range may be efficiently emitted.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a perspective view illustrating a display device according to an embodiment of the present disclosure.

FIG. 2 is a plan view illustrating the pixel areas of the display device of FIG. 1.

FIG. 3 is a cross-sectional view illustrating an embodiment taken along line I-I′ of the display device of FIG. 2.

FIG. 4 is an enlarged cross-sectional view of the pixel electrode layers of FIG. 3.

FIG. 5 is an enlarged cross-sectional view of area A of FIG. 4.

FIGS. 6 to 37 are cross-sectional views illustrating a method of manufacturing the display device of FIG. 3.

FIG. 38 is a block-diagram illustrating an electronic device according to an embodiment of the present disclosure.

FIG. 39 is a schematic view of the electronic device according to various embodiments of FIG. 38.

### DETAILED DESCRIPTION

Regarding embodiments of the present disclosure disclosed in this text, specific structural and functional descriptions are illustrative for a purpose of explaining the embodiments of the present disclosure, and the embodiments of the present disclosure may be implemented in various forms and should not be construed as limited to the embodiments described in.

Since the present disclosure may be subject to various changes and may have various forms, specific embodiments will be illustrated in the drawings and described in detail in the text. However, this is not intended to limit the present disclosure to a specific disclosed form, and should be understood to include all changes, equivalents, and substitutes included in the spirit and technical scope of the present disclosure.

Terms such as first, second, and the like may be used to describe various components, but the components should not be limited by the terms. The terms may be used for a purpose of distinguishing one component from another component. For example, a first component may be referred to as a second component, and similarly, the second component may be referred to as a first component without departing from the scope of the present disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for a purpose of describing particular example embodiments and is not intended to be limiting of the present inventive concept and embodiments of the present disclosure. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, and the like are used to explain a relationship between components illustrated in the drawings. The terms are relative concepts and are explained based on the direction indicated in the drawings.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially the same amount” means approximately or actually the same amount.

Unless otherwise defined, all terms (including technical and scientific terms) used herein have a same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. Same reference numerals are used for same components in the drawings, and redundant descriptions of same components will be omitted.

In this specification, a plane may be defined by a first direction D1 and a second direction D2 that intersects the first direction D1. For example, the second direction D2 may be perpendicular to the first direction D1. In some aspects, a third direction D3 may be a normal direction of the plane. That is, the third direction D3 may be perpendicular to the plane formed by the first direction D1 and the second direction D2.

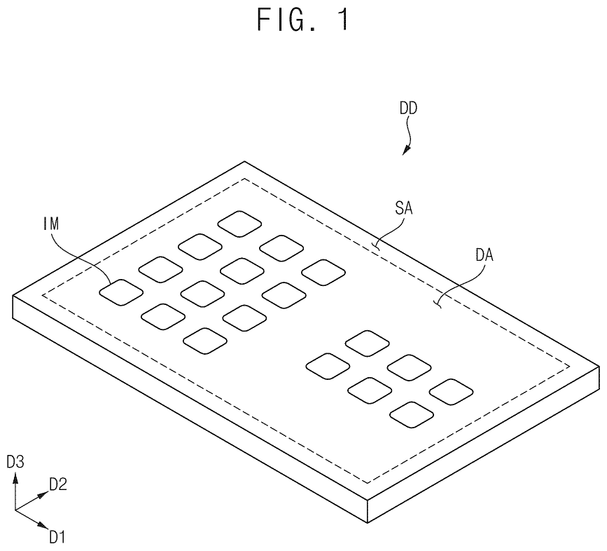

FIG. 1 is a perspective view illustrating a display device according to an embodiment of the present disclosure.

Referring to FIG. 1, a display device DD may include a display area DA and a peripheral area SA. The display area DA may be surrounded by the peripheral area SA.

The display area DA may be an area that generates light or may display an image by controlling a transmittance of light provided from an external light source. The peripheral area SA may be an area that does not display an image. However, embodiments of the present disclosure are not necessarily limited thereto, and at least a portion of the peripheral area SA may display an image.

The display area DA may display a plurality of images IM. Users may receive information from the display device DD through the plurality of images IM.

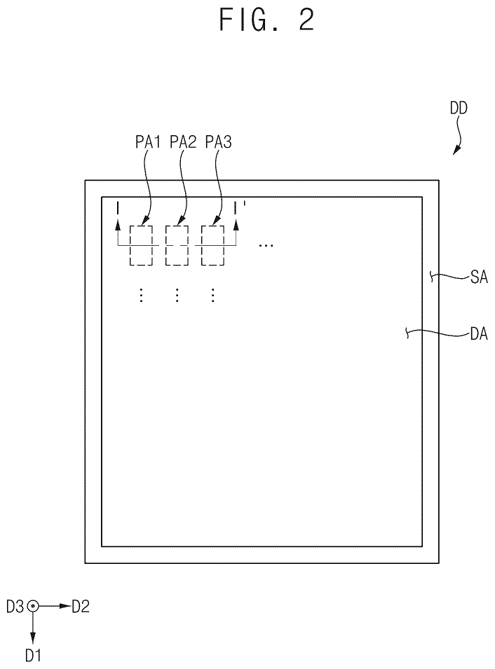

FIG. 2 is a plan view illustrating the pixel areas of the display device of FIG. 1.

Referring to FIG. 2, a first pixel area PA1, a second pixel area PA2, and a third pixel area PA3 may be defined in the display area DA of the display device DD. The first pixel area PA1, the second pixel area PA2, and the third pixel area PA3 may be disposed side by side in the second direction D2.

For example, the second pixel area PA2 may be defined adjacent to the first pixel area PA1 in the second direction D2, and the third pixel area PA3 may be defined adjacent to the second pixel area PA2 in the second direction D2. However, the embodiment of the present disclosure is not necessarily limited thereto. The first pixel area PA1, the second pixel area PA2, and the third pixel area PA3 may be defined in a matrix shape in the first direction D1 and/or the second direction D2.

In FIG. 2, a planar shape of the display device DD is illustrated as being a square, but the embodiment of the present disclosure is not necessarily limited thereto. A planar shape of the display device DD may include various shapes such as, for example, a circle or a polygon.

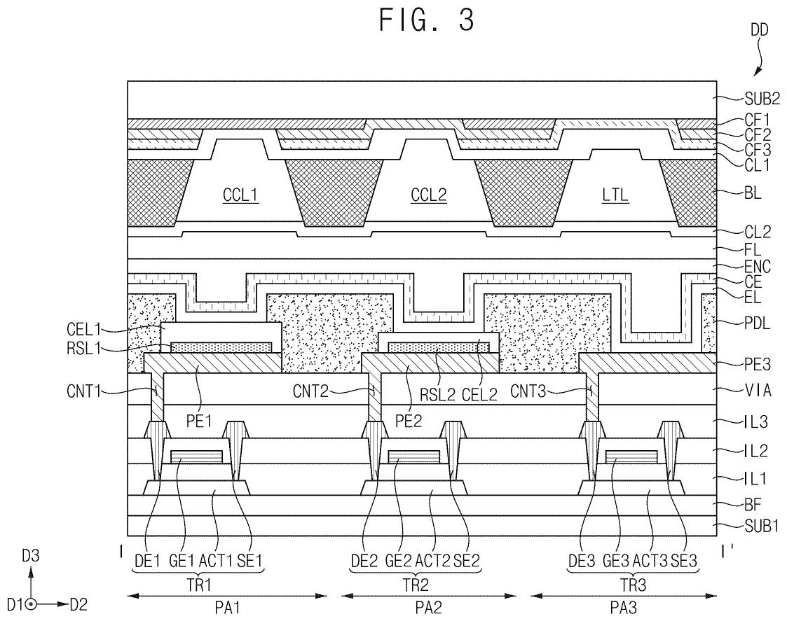

FIG. 3 is a cross-sectional view illustrating an embodiment taken along line I-I′ of the display device of FIG. 2.

Referring to FIGS. 2 and 3, the display device DD may include a first substrate SUB1, a buffer layer BF, first, second, and third insulating layers IL1, IL2, and IL3, first, second, and third transistors TR1, TR2, and TR3, a via layer VIA, first, second, and third pixel electrode layers PE1, PE2, and PE3, first and second resonant layers RSL1, RSL2, first and second conductive layers CEL1, CEL2, a pixel defining layer PDL, an emitting layer EL, a common electrode CE, an encapsulating layer ENC, a filling layer FL, first and second capping layers CL1, CL2, first and second color conversion layers CCL1, CCL2, a light transmitting layer LTL, a light blocking member BL, first, second, and third color filters CF1, CF2, and CF3, and a second substrate SUB2.

The first transistor TR1 may include a first active layer ACT1, a first gate electrode GE1, a first source electrode SE1, and a first drain electrode DE1. The second transistor TR2 may include a second active layer ACT2, a second gate electrode GE2, a second source electrode SE2, and a second drain electrode DE2. The third transistor TR3 may include a third active layer ACT3, a third gate electrode GE3, a third source electrode SE3, and a third drain electrode DE3.

First, configurations of the first substrate SUB1 to the encapsulating layer ENC will be sequentially described.

The first substrate SUB1 may include a transparent material or an opaque material. The first substrate SUB1 may include a transparent resin substrate. Examples of the transparent resin substrate may include a polyimide substrate or the like. In this case, the polyimide substrate may include a first organic layer, a first barrier layer, a second organic layer, or the like. Optionally, the first substrate SUB1 may include a quartz substrate, a synthetic quartz substrate, a calcium fluoride substrate, a fluorine-doped quartz substrate, a soda-lime glass substrate, a non-alkali glass substrate, or the like. These may be used alone or in combination with each other.

The buffer layer BF may be disposed on the first substrate SUB1. The buffer layer BF may prevent metal atoms or impurities from diffusing from the first substrate SUB1 to the first, second, and third transistors TR1, TR2, and TR3. In some aspects, the buffer layer BF may improve a flatness of the surface of the first substrate SUB1 when a surface of the first substrate SUB1 is not uniform. For example, the buffer layer BF may include an inorganic material such as, for example, silicon oxide, silicon nitride, silicon oxynitride, or the like. These may be used alone or in combination with each other.

The first, second, and third active layers ACT1, ACT2, and ACT3 may be disposed on the buffer layer BF. Each of the first, second, and third active layers ACT1, ACT2, and ACT3 may include a metal oxide semiconductor, an inorganic semiconductor (e.g., amorphous silicon, poly silicon), or an organic semiconductor. However, the embodiment of the present disclosure is not necessarily limited thereto. Each of the first, second, and third active layers ACT1, ACT2, and ACT3 may include a source region, a drain region, and a channel region positioned between the source region and the drain region. The first, second, and third active layers ACT1, ACT2, and ACT3 may be formed through a same process and may include a same material.

The first, second, and third active layers ACT1, ACT2, and ACT3 may be disposed in the first, second, and third pixel areas PA1, PA2, and PA3, respectively. For example, the first active layer ACT1 may be disposed in the first pixel area PA1. The second active layer ACT2 may be disposed in the second pixel area PA2. The third active layer ACT3 may be disposed in the third pixel area PA3.

The first insulating layer IL1 may be disposed on the buffer layer BF. Specifically, the first insulating layer IL1 may cover the first, second, and third active layers ACT1, ACT2, and ACT3 and may be disposed on the buffer layer BF. For example, the first insulating layer IL1 may include an inorganic insulating material.

The first, second, and third gate electrodes GE1, GE2, and GE3 may be disposed on the first insulating layer IL1. The first gate electrode GE1 may overlap the channel area of the first active layer ACT1. The second gate electrode GE2 may overlap with the channel region of the second active layer ACT2. The third gate electrode GE3 may overlap with the channel region of the third active layer ACT3.

Each of the first, second, and third gate electrodes GE1, GE2, and GE3 may include a metal, an alloy metal nitride, a conductive metal oxide, a transparent conductive material, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide, indium zinc oxide, or the like. Examples of the metal nitride may include aluminum nitride (AlNx), tungsten nitride (WNx), chromium nitride (CrNx), or the like. These may be used alone or in combination with each other. The first, second, and third gate electrodes GE1, GE2, and GE3 may be formed through a same process and may include a same material.

The second insulating layer IL2 may be disposed on the first insulating layer IL1. Specifically, the second insulating layer IL2 may cover the first, second, and third gate electrodes GE1, GE2, and GE3 and may be disposed on the first insulating layer IL1. The second insulating layer IL2 may include a same material as the first insulating layer IL1.

The first, second, and third source electrodes SE1, SE2, and SE3 and the first, second, and third drain electrodes DE1, DE2, and DE3 may be disposed on the second insulating layer IL2.

Specifically, each of the first source electrode SE1 and the first drain electrode DE1 may be electrically connected to the first active layer ACT1 by penetrating the first insulating layer IL1 and the second insulating layer IL2. Each of the second source electrode SE2 and the second drain electrode DE2 may be electrically connected to the second active layer ACT2 by penetrating the first insulating layer IL1 and the second insulating layer IL2. Each of the third source electrode SE3 and the third drain electrode DE3 may be electrically connected to the third active layer ACT3 by penetrating the first insulating layer IL1 and the second insulating layer IL2. For example, the first, second, and third source electrodes SE1, SE2, and SE3 and the first, second, and third drain electrodes DE1, DE2, and DE3 may include a conductive metal material.

The third insulating layer IL3 may be disposed on the second insulating layer IL2. Specifically, the third insulating layer IL3 may cover the first, second, and third source electrodes SE1, SE2, and SE3 and the first, second, and third drain electrodes DE1, DE2, and DE3, and may be disposed on the second insulating layer IL2. The third insulating layer IL3 may include a same material as the first insulating layer IL1 and the second insulating layer IL2.

The via layer VIA may be disposed on the third insulating layer IL3. The via layer VIA may include an organic insulating material. The via layer VIA may be formed, for example, on the display area DA and a portion of the peripheral area SA adjacent to the display area DA, without being formed on other areas. An upper surface of the via layer VIA may be flat. Accordingly, configurations directly disposed on an upper surface of the via layer VIA may have a same height with respect to the first substrate SUB1.

In an embodiment, first, second, and third contact holes HL1, HL2, and HL3 may be defined in the via layer VIA. The first, second, and third contact holes HL1, HL2, and HL3 may penetrate a portion of the via layer VIA and the third insulating layer IL3 to expose an upper surface of each of the first, second, and third drain electrodes DE1, DE2, and DE3.

For example, the first contact hole HL1 may expose an upper surface of the first drain electrode DE1. The second contact hole HL2 may expose an upper surface of the second drain electrode DE2. The third contact hole HL3 may expose an upper surface of the third drain electrode DE3.

The first, second, and third pixel electrode layers PE1, PE2, and PE3 may be disposed on the via layer VIA. Specifically, each of the first, second, and third pixel electrode layers PE1, PE2, and PE3 may be disposed on the via layer VIA while filling each of the first, second, and third contact holes HL1, HL2, and HL3. Accordingly, the first, second, and third pixel electrode layers PE1, PE2, and PE3 may be electrically connected to the first, second, and third drain electrodes DE1, DE2, and DE3 through the first, second, and third contact holes HL1, HL2, and HL3, respectively.

In an embodiment, a height of an upper surface of each of the first, second, and third pixel electrode layers PE1, PE2, and PE3 with respect to the first substrate SUB1 may be the same. That is, respective thicknesses of the first, second, and third pixel electrode layers PE1, PE2, and PE3 may be the same as one another, and accordingly, respective upper surfaces of the first, second, and third pixel electrode layers PE1, PE2, and PE3 disposed on the via layer VIA having a flat upper surface may have the same height with respect to the first substrate SUB1.

Each of the first and second resonant layers RSL1, RSL2 may be disposed on the first and second pixel electrode layers PE1, PE2. That is, the first resonant layer RSL1 may be disposed on the first pixel electrode layer PE1, and the second resonant layer RSL2 may be disposed on the second pixel electrode layer PE2. The first and second resonant layers RSL1, RSL2 may include a transparent material.

For example, the first and second resonant layers RSL1, RSL2 may include an inorganic material. Examples of materials included in the inorganic material may include at least one of silicon oxide, silicon nitride, and silicon oxynitride. These may be used alone or in combination with each other. However, the embodiments of the present disclosure are not necessarily limited thereto.

In an embodiment, the first and second resonant layers RSL1, RSL2 may be disposed in the first and second pixel areas PA1, PA2, and a resonant layer may not be disposed in the third pixel area PA3. For example, if each of the first, second, and third pixel areas PA1, PA2, and PA3 is an area emitting red, green, and blue, a resonant layer may not be disposed in one of the first, second, and third pixel areas PA1, PA2, and PA3. Accordingly, the third pixel electrode layer PE3 may be in direct contact with the light emitting layer EL.

In an embodiment, a thickness of the first resonant layer RSL1 and a thickness of the second resonant layer RSL2 may be the same (e.g., equal to one another). Accordingly, a height of an upper surface of the first resonant layer RSL1 and a height of an upper surface of the second resonant layer RSL2 may be the same with respect to the first substrate SUB1.

The first and second conductive layers CEL1, CEL2 may be disposed on the first and second resonant layers RSL1, RSL2, respectively. Specifically, the first conductive layer CEL1 may be disposed on the first resonant layer RSL1 and may cover the first resonant layer RSL1. The second conductive layer CEL2 may be disposed on the second resonant layer RSL2 and may cover the second resonant layer RSL2.

The first and second conductive layers CEL1, CEL2 may include a transparent conductive oxide. For example, the first and second conductive layers CEL1, CEL2 may include indium (In) and tin (Sn). These may be used alone or in combination. However, the embodiment of the present disclosure is not necessarily limited thereto.

In an embodiment, the first and second conductive layers CEL1, CEL2 may be electrically connected to the first and second pixel electrode layers PE1, PE2, respectively.

For example, as illustrated in FIG. 3, the first conductive layer CELL may contact the first pixel electrode layer PE1 while covering a side surface of the first resonant layer RSL1. The second conductive layer CEL2 may contact the second pixel electrode layer PE2 while covering a side surface of the second resonant layer RSL2. Accordingly, signals transmitted from each of the first and second pixel electrode layers PE1, PE2 may be transmitted to the light emitting layer EL through the first and second conductive layers CEL1, CEL2.

In an embodiment, a thickness of the first conductive layer CELL and a thickness of the second conductive layer CEL2 may be different from each other. Accordingly, a height of an upper surface of each of the first conductive layer CELL with respect to the first substrate SUB1 and a height of the second conductive layer CEL2 with respect to the first substrate SUB1 may be different. For example, a height of the upper surface of the first conductive layer CELL based on the first substrate SUB1 may be higher than a height of an upper surface of the second conductive layer CEL2.

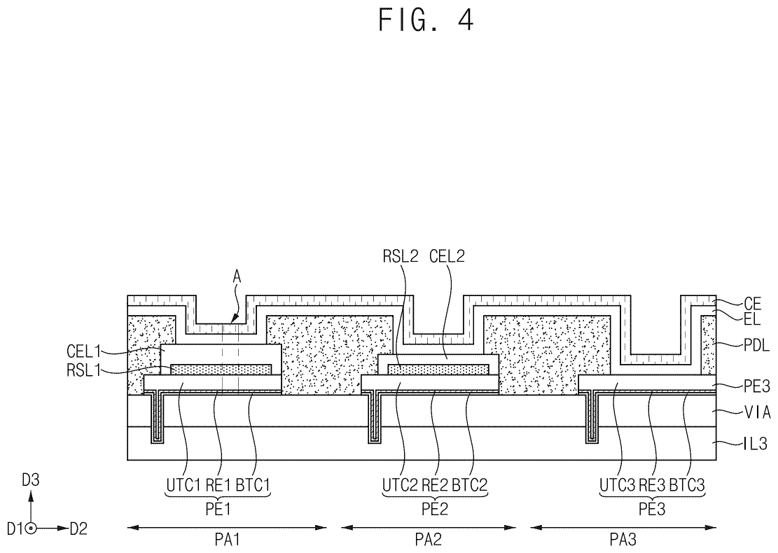

Since respective thicknesses of the first conductive layer CELL and the second conductive layer CEL2 are different from one another, a distance between the first pixel electrode layer PE1 and the common electrode CE may be different from a distance between the second pixel electrode layer PE2 and the common electrode CE. This will be described later with reference to FIG. 4.

The pixel defining film PDL may be disposed on the first, second, and third pixel electrode layers PE1, PE2, and PE3. Specifically, the pixel defining film PDL may expose at least a portion of an upper surface of each of the first conductive layer CELL, the second conductive layer CEL2, and the third pixel electrode layer PE3. The pixel defining layer PDL may include an inorganic insulating material or an organic insulating material.

The light emitting layer EL may be disposed on the first conductive layer CELL, the second conductive layer CEL2, and the third pixel electrode layer PE3. The light emitting layer EL may also be disposed on the pixel defining layer PDL. That is, the light emitting layer EL may be disposed continuously on the first conductive layer CEL1, the second conductive layer CEL2, the third pixel electrode layer PE3, and the pixel defining layer PDL.

In an embodiment, the light emitting layer EL may be an organic light emitting layer or an inorganic light emitting layer. For example, the light emitting layer EL may emit white light. That is, the light emitting layer EL may emit white light by stacking a red light emitting material, a green light emitting material, and a blue light emitting material in a tandem structure. In another example, the light emitting layer EL may emit blue light. However, the embodiment of the present disclosure is not necessarily limited thereto.

The common electrode CE may be disposed on the light emitting layer EL. The common electrode CE may be disposed continuously on the light emitting layer EL. That is, the common electrode CE may be a plate electrode. The light emitting layer EL may emit light based on a voltage difference between the pixel electrode layers PE1, PE2, and PE3 and the common electrode CE. The common electrode CE may include a transparent conductive material or a semitransparent conductive material.

The encapsulating layer ENC may be disposed on the common electrode CE. The encapsulating layer ENC may include at least one inorganic encapsulating layer and at least one organic encapsulating layer. In an embodiment, the inorganic encapsulating layer and the organic encapsulating layer may be disposed alternately. For example, the organic encapsulating layer may include a polymer cured material such as, for example, polyacrylate, epoxy resin, silicone resin, or the like. For example, the inorganic encapsulating layer film may include silicon oxide, silicon nitride, silicon carbide, aluminum oxide, tantalum oxide, hafnium oxide, zirconium oxide, titanium oxide, or the like.

The filling layer FL may be disposed on the encapsulating layer ENC. Specifically, the filling layer FL may be disposed between the first substrate SUB1 and the second substrate SUB2 in a cross-sectional view. That is, the filling layer FL may fill a space between the first substrate SUB1 and the second substrate SUB2. The filling layer FL may include a material that may transmit light. For example, the filling layer FL may include an organic material that may transmit light. Examples of materials that may be used in the filling layer FL may include a silicone-based resin, an epoxy-based resin, or the like. These may be used alone or in combination with each other. However, the present disclosure is not necessarily limited thereto.

Hereinafter, configurations sequentially laminated from the second substrate SUB2 to the second capping layer CL2 will be described. That is, configurations laminated in an opposite direction of the third direction D3 from the second substrate SUB2 will be described.

The second substrate SUB2 may transmit light emitted from the light emitting layer EL. That is, the second substrate SUB2 may include a transparent material such that light may pass through. For example, the second substrate SUB2 may be formed of a transparent resin substrate. The second substrate SUB2 may include an insulating material such as, for example, glass or plastic. Optionally, the second substrate SUB2 may include an organic polymer material such as, for example, polycarbonate (PC), polyethylene (PE), or polypropylene (PP). These may be used alone or in combination with each other. However, the embodiment of the present disclosure is not necessarily limited thereto.

The color filters CF1, CF2, and CF3 may be disposed under the second substrate SUB2. Each of the color filters CF1, CF2, and CF3 may selectively transmit light having a specific wavelength.

The first color filter CF1 may selectively transmit light of a first color (e.g., red light). The first color filter CF1 may overlap the first pixel area PA1 and the light blocking member BL in a plan view. In this case, the first color filter CF1 may not overlap the second pixel area PA2 and the third pixel area PA3 in a plan view.

The second color filter CF2 may selectively transmit light of a second color (e.g., green light). The second color filter CF2 may overlap the second pixel area PA2 and the light blocking member BL in a plan view. In this case, the second color filter CF2 may not overlap the first pixel area PA1 and the third pixel area PA3 in a plan view.

The third color filter CF3 may selectively transmit light of a third color (e.g., blue light). The third color filter CF3 may overlap the third pixel area PA3 and the light blocking member BL in a plan view. In this case, the third color filter CF3 may not overlap the first pixel area PA1 and the second pixel area PA2 in a plan view.

The first capping layer CL1 may be disposed under the color filters CF1, CF2, and CF3. The first capping layer CL1 may cover the color filters CF1, CF2, and CF3. The first capping layer CL1 may be disposed along a profile of the color filters CF1, CF2, and CF3. The first capping layer CL1 may block external impurities and prevent contamination of the color filters CF1, CF2, and CF3. For example, the first capping layer CL1 may include an inorganic material such as, for example, silicon oxide, silicon nitride, silicon oxynitride, or the like. These may be used alone or in combination with each other. However, the embodiments of the present disclosure are not necessarily limited thereto.

The light-blocking member BL may be disposed under the first capping layer CL1. The light-blocking member BL may expose at least a portion of one surface of the first capping layer CL1. The light-blocking member BL may block light emitted from the light emitting layer EL from passing through the second substrate SUB2. For example, the light-blocking member BL may define a plurality of areas overlapping each of the first, second, and third pixel areas PA1, PA2, and PA3 under the color filters CF1, CF2, and CF3. The light-blocking member BL may include an organic material. Each of the plurality of areas may be filled with a first color conversion layer CCL1, a second color conversion layer CCL2, and a light-transmitting layer LTL. That is, the display device DD may be a quantum dot display including the first color conversion layer CCL1, the second color conversion layer CCL2, and the light transmitting layer LTL. However, the present disclosure is not necessarily limited thereto.

The first color conversion layer CCL1 may be disposed to overlap the first pixel area PA1 in a plan view. The first color conversion layer CCL1 may include first quantum dots, first scattering particles, and a first photosensitive polymer that are excited by light emitted from the light emitting layer EL and emit light of a first color (e.g., red light).

The second color conversion layer CCL2 may be disposed to overlap the second pixel area PA2 in a plan view. The second color conversion layer CCL2 may include second quantum dots, second scattering particles, and a second photosensitive polymer that are excited by light emitted from the light emitting layer EL and emit light of a second color (e.g., green light).

The light transmitting layer LTL may be disposed to overlap the third pixel area PA3 in a plan view. The light transmitting layer LTL may transmit light emitted from the light emitting layer EL to emit blue light. The light transmitting layer LTL may include a third photosensitive polymer.

The second capping layer CL2 may be disposed under the light blocking member BL, the first color conversion layer CCL1, the second color conversion layer CCL2, and the light transmitting layer LTL. As illustrated in FIG. 3, the second capping layer CL2 may be disposed along a profile of the light blocking member BL, the first color conversion layer CCL1, the second color conversion layer CCL2, and the light transmitting layer LTL. The second capping layer CL2 may prevent moisture, or the like from flowing into the first color conversion layer CCL1, the second color conversion layer CCL2, and the light transmitting layer LTL. For example, the second capping layer CL2 may include an inorganic material such as, for example, silicon oxide, silicon nitride, silicon oxynitride, or the like. These may be used alone or in combination. However, the embodiment of the present disclosure is not necessarily limited thereto.

However, although the display device DD of the present disclosure is described with reference to an organic light emitting display device (OLED), a configuration of the present disclosure is not necessarily limited thereto. In other embodiments, the display device DD may include a liquid crystal display device (LCD), a field emission display device (FED), a plasma display device (PDP), or an electrophoretic display device (EPD).

FIG. 4 is an enlarged cross-sectional view of the pixel electrode layers of FIG. 3.

Referring to FIGS. 3 and 4, the first pixel electrode layer PE1 may include a first lower electrode layer BTC1, a first reflective electrode layer RE1, and a first upper electrode layer UTC1. The first lower electrode layer BTC1, the first reflective electrode layer RE1, and the first upper electrode layer UTC1 may be sequentially disposed on the first substrate SUB1. For example, the first lower electrode layer BTC1 may be disposed on the via layer VIA, the first reflective electrode layer RE1 may be disposed on the first lower electrode layer BTC1, and the first upper electrode layer UTC1 may be disposed on the first reflective electrode layer RE1, sequentially.

The second pixel electrode layer PE2 may include a second lower electrode layer BTC2, a second reflective electrode layer RE2, and a second upper electrode layer UTC2. The second lower electrode layer BTC2, the second reflective electrode layer RE2, and the second upper electrode layer UTC2 may be sequentially disposed on the first substrate SUB1. For example, the second lower electrode layer BTC2 may be disposed on the via layer VIA, the second reflective electrode layer RE2 may be disposed on the second lower electrode layer BTC2, and the second upper electrode layer UTC2 may be disposed on the second reflective electrode layer RE2, sequentially.

The third pixel electrode layer PE3 may include a third lower electrode layer BTC3, a third reflective electrode layer RE3, and a third upper electrode layer UTC3. The third lower electrode layer BTC3, the third reflective electrode layer RE3, and the third upper electrode layer UTC3 may be sequentially disposed on the first substrate SUB1. For example, the third lower electrode layer BTC3 may be disposed on the via layer VIA, the third reflective electrode layer RE3 may be disposed on the third lower electrode layer BTC3, and the third upper electrode layer UTC3 may be disposed on the third reflective electrode layer RE3, sequentially.

In an embodiment, respective thicknesses of the first, second, and third lower electrode layers BTC1, BTC2, and BTC3 may be the same as one another (e.g., may be equal to one another). That is, the first, second, and third lower electrode layers BTC1, BTC2, and BTC3 may have the same thickness and may be disposed spaced apart from each other on the via layer VIA.

The first lower electrode layer BTC1 may be disposed along a profile of the first contact hole HL1. The second lower electrode layer BTC2 may be disposed along a profile of the second contact hole HL2. The third lower electrode layer BTC3 may be disposed along a profile of the third contact hole HL3.

In an embodiment, the first, second, and third lower electrode layers BTC1, BTC2, and BTC3 may include a transparent conductive oxide. For example, the first, second, and third lower electrode layers BTC1, BTC2, and BTC3 may include indium (In) and tin (Sn). However, the embodiment of the present disclosure is not necessarily limited thereto.

The first, second, and third reflective electrode layers RE1, RE2, and RE3 may be disposed along a profile of the first, second, and third lower electrode layers BTC1, BTC2, and BTC3, respectively. For example, the first reflective electrode layer RE1 may extend into an interior of the first contact hole HL1. The second reflective electrode layer RE2 may extend into an interior of the second contact hole HL2. The third reflective electrode layer RE3 may extend into an interior of the third contact hole HL3.

In an embodiment, respective thicknesses of the first, second, and third reflective electrode layers RE1, RE2, and RE3 may be the same (e.g., may be equal to one another). That is, the first, second, and third reflective electrode layers RE1, RE2, and RE3 may have the same thickness and may be disposed on the first, second, and third lower electrode layers BTC1, BTC2, and BTC3.

The first, second, and third upper electrode layers UTC1, UTC2, and UTC3 may be disposed on the first, second, and third reflective electrode layers RE1, RE2, and RE3, respectively. The first, second, and third upper electrode layers UTC1, UTC2, and UTC3 may include a same material as the first, second, and third lower electrode layers BTC1, BTC2, and BTC3. In some aspects, the first, second, and third upper electrode layers UTC1, UTC2, and UTC3 may further include other materials not included in the first, second, and third lower electrode layers BTC1, BTC2, and BTC3. That is, the first, second, and third upper electrode layers UTC1, UTC2, and UTC3 may be transparent conductive oxides that further include other materials in addition to indium (In) and tin (Sn). For example, the first, second, and third upper electrode layers UTC1, UTC2, and UTC3 may further include silver (Ag), magnesium (Mg), aluminum (Al), platinum (Pt), gold (Au), nickel (Ni), and chromium (Cr).

In an embodiment, the first lower electrode layer BTC1, the first upper electrode layer UTC1, and the first conductive layer CELL may include a same material. The second lower electrode layer BTC2, the second upper electrode layer UTC2, and the second conductive layer CEL2 may include a same material.

In an embodiment, heights of respective upper surfaces of the first, second, and third upper electrode layers UTC1, UTC2, and UTC3 may be the same with respect to the first substrate SUB1. That is, the first, second, and third upper electrode layers UTC1, UTC2, and UTC3 may be manufactured in the same process, such that heights of respective upper surfaces of the first, second, and third upper electrode layers UTC1, UTC2, and UTC3 may be the same with respect to the first substrate SUB1.

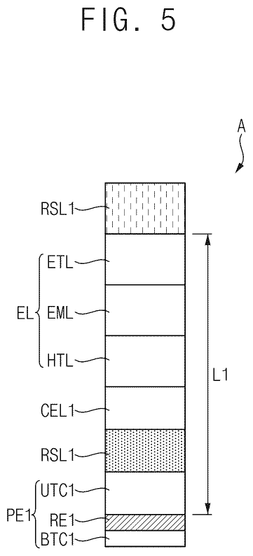

FIG. 5 is an enlarged cross-sectional view of area A of FIG. 4. Specifically, FIG. 5 is a cross-sectional view illustrating the cross-sectional view of the first pixel electrode layer PE1, the first resonant layer RSL1, the first conductive layer CEL1, the light emitting layer EL, and the common electrode CE illustrated in FIG. 3. The light emitting layer EL illustrated in FIG. 5 may also be disposed on the second pixel electrode layer PE2 and the third pixel electrode layer PE3 illustrated in FIG. 4. Therefore, overlapping content may be omitted or simplified.

Referring to FIGS. 3, 4, and 5, the light emitting layer EL may include a hole transport layer HTL, a light emitting material layer EML, and an electron transport layer ETL. Although the light emitting layer EL is illustrated as including three components in FIG. 5, the embodiment of the present disclosure is not necessarily limited thereto. The light emitting layer EL may further include functional layers including a hole injection layer, an electron injection layer, or the like.

The hole transport layer HTL may be disposed on the first pixel electrode layer PE1. The hole transport layer HTL may inject holes into the light emitting material layer EML. The light emitting layer EL may include a plurality of hole transport layers. The hole transport layer HTL may include various organic materials, including copper phthalocyanine (CuPc), N,N-di(naphthalene-1-yl)-N,N′-diphenyl-benzidine (NPB), tris-8-hydroxyquinoline aluminum (Alq3), or the like. These may be used alone or in combination. However, the embodiments of the present disclosure are not necessarily limited thereto.

The light emitting material layer EML may be disposed on the hole transport layer HTL. The light emitting material layer EML may emit light of a preset color. The light emitting layer EL may include a plurality of light emitting material layers.

In an embodiment, the light emitting material layer EML may include at least one of a red material that emits red light, a blue material that emits blue light, and a green material that emits green light. For example, the light emitting layer EL may include a red material, a blue material, and a green material. That is, the light emitting layer EL may emit white light in which red, blue, and green light are mixed and emitted. In another example, the light emitting layer EL may emit blue light. However, the present disclosure is not necessarily limited thereto.

In an embodiment, a first distance L1, which is a distance between the first reflective electrode layer RE1 and the common electrode CE in a cross-sectional view, may be defined. A portion of the light emitted from the light emitting layer EL may pass through the common electrode CE. However, another portion of the light emitted from the light emitting layer EL, that is, a first light, may be reflected from the common electrode CE in a direction opposite to the third direction D3 and reflected again by the first reflective electrode layer RE1 of the first pixel electrode layer PE1.

Likewise, a portion of the first light reflected by the first reflective electrode layer RE1 may pass through the common electrode CE, but a portion of the first light, that is, a second light, may be reflected again by the common electrode CE and then reflected again by the first reflective electrode layer RE1. Accordingly, the first light and the second light may form a standing wave between the common electrode CE and the first reflective electrode layer RE1 in a cross-sectional view. As the first light and the second light form a standing wave, a third light having a greater intensity than the first light and the second light may be formed.

As illustrated in FIGS. 3 and 5, the constructively interfered third light may pass through the first color conversion layer CCL1 and the first color filter CF1 that selectively transmits the first color. That is, if a wavelength of the third light whose intensity is increased matches a wavelength of the first color, a light emission efficiency of the display device DD may be increased. Since the third light constructively interferes within the first distance L1 on the cross-sectional view, the first distance L1 may have a certain relationship with a size of a wavelength of the third light. That is, in order to increase a light emission efficiency of the display device DD, a wavelength of the first color matching a wavelength of the third light and the first distance L1, which is a resonance distance, may have a certain relationship.

In summary, the first distance L1 and the wavelength of the first color may satisfy following equation 1.

L=(λ/2)×N [Equation 1]

Here, L is the resonance distance (e.g., the first distance L1 of FIG. 5), λ is a median value of the wavelength of the first color, and N is a natural number.

Referring to the equation 1, when the first color is red, since a wavelength is about 610 nm to about 700 nm, λ is about 655 nm, which is a median of the wavelength, and the resonance distance L may be an integer multiple of about 377.5 nm, which is a median of the wavelength of the first color.

Referring to the equation 1, when the first color is green, since the wavelength is about 500 nm to about 570 nm, λ is about 535 nm, which is a median of the wavelength, and the resonance distance L may be an integer multiple of about 267.5 nm, which is a median of the wavelength of the first color.

Referring to the equation 1, since the wavelength is about 450 nm to about 500 nm when the first color is red, λ is about 475 nm, which is the middle value of the wavelength, and the resonance distance L may be an integer multiple of about 237.5 nm, which is the middle value of the wavelength of the first color.

As illustrated in FIGS. 3, 4, and 5, a distance at which the light emitted from the light emitting layer EL undergoes constructive interference may be controlled through the first and second resonant layers RSL1, RSL2 and the first and second conductive layers CEL1, CEL2. That is, a second distance may be defined between the second reflective electrode layer RE2 and the common electrode CE, and a third distance may be defined between the third reflective electrode layer RE3 and the common electrode CE. The first distance L1, the second distance, and the third distance may be different from each other.

As a result, respective thicknesses of the first conductive layers CEL1 and the second conductive layer CEL2 are different from one another, the first distance L1 and the second distance may be different. In some aspects, the values of the first distance L1, the second distance, and the third distance may be different based on a presence or absence of the first and second resonant layers RSL1, RSL2. Accordingly, wavelengths in which the light emitted from each of the first, second, and third pixel areas PA1, PA2, and PA3 constructively interfere may be different from one another. That is, by adjusting the values of the first distance L1, the second distance, and the third distance, wavelengths overlapping with colors of each of the first, second, and third color filters CF1, CF2, and CF3 may be constructively interfered. Therefore, light of wavelengths overlapping with the colors of each of the first, second, and third color filters CF1, CF2, and CF3 may be efficiently emitted.

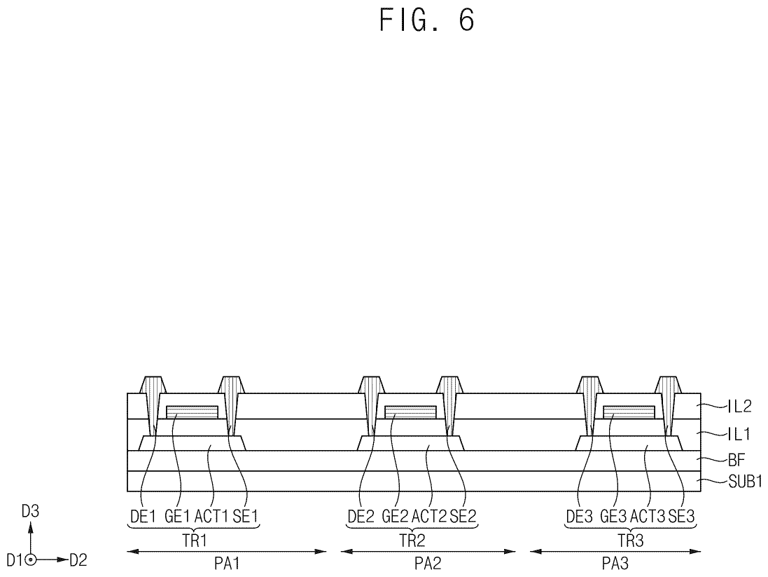

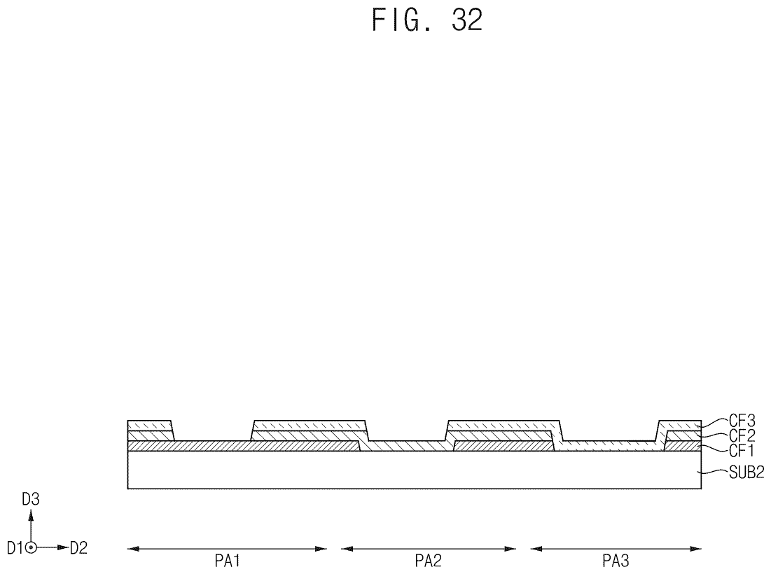

FIGS. 6 to 37 are cross-sectional views illustrating a method of manufacturing the display device of FIG. 3. Specifically, a method of manufacturing the first substrate SUB1 to the encapsulating layer ENC will be described with reference to FIGS. 6 to 31. A method of manufacturing the second substrate SUB2 to the second capping layer CL2 from will be described with reference to FIGS. 32 to 36.

In the descriptions of the method and processes herein, the operations may be performed in a different order than the order shown and/or described, or the operations may be performed in different orders or at different times. Certain operations may also be left out, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 6, the method may include forming the first transistor TR1 in the first pixel area PA1, forming the second transistor TR2 in the second pixel area PA2, and forming the third transistor TR3 in the third pixel area PA3. The first active layer ACT1 of the first transistor TR1, the second active layer ACT2 of the second transistor TR2, and the third active layer ACT3 of the third transistor TR3 may be formed on a same layer. That is, the first, second, and third active layers ACT1, ACT2, and ACT3 may be formed of a same material in a same process.

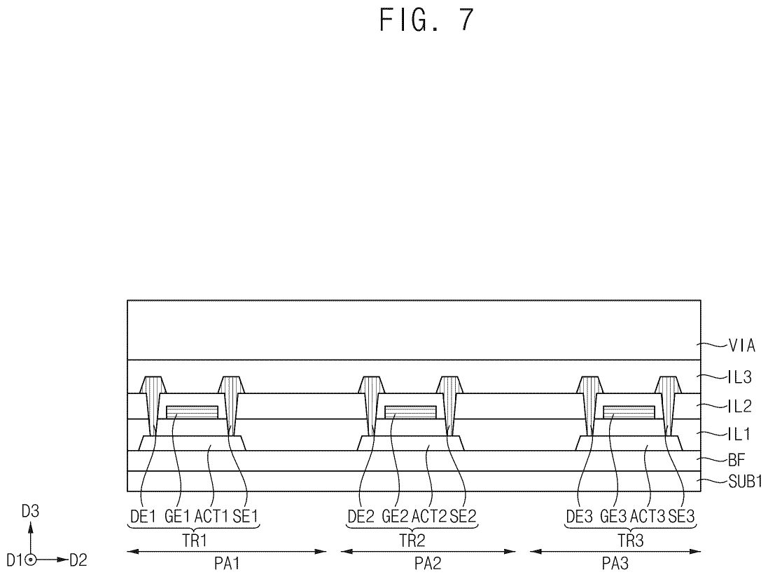

Referring further to FIG. 7, the method may include sequentially forming the third insulating layer IL3 and the via layer VIA on the second insulating layer IL2. The third insulating layer IL3 may be formed on the second insulating layer IL2 while covering a portion of each of the first transistor TR1, the second transistor TR2, and the third transistor TR3. The via layer VIA may include an organic material. An upper surface of the via layer VIA may be flat.

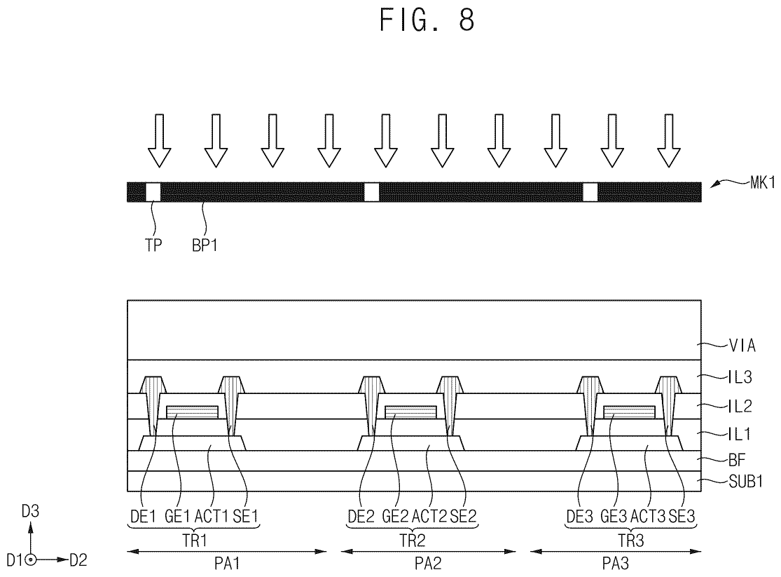

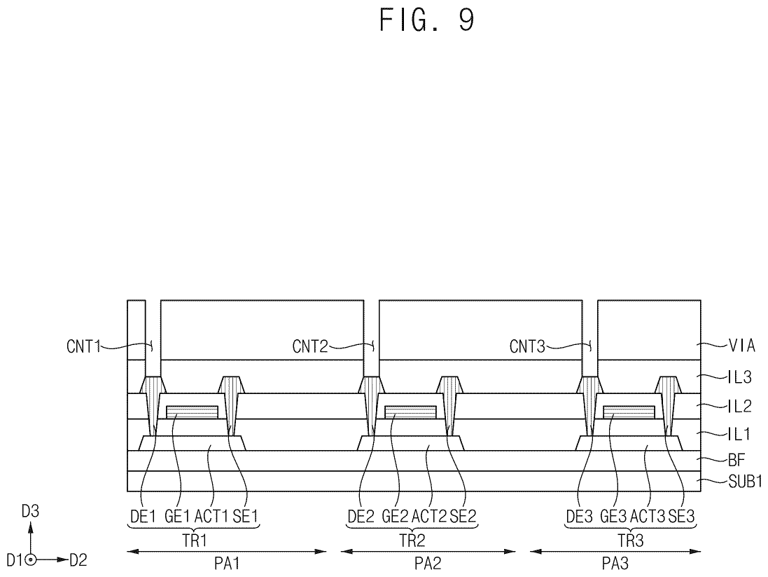

Referring further to FIGS. 8 and 9, the method may include disposing a first mask MK1 on the via layer VIA. A transmission portion TP that overlaps the first, second, and third drain electrodes DE1, DE2, and DE3 in a plan view and a first light-shielding portion BP1 may be defined on the first mask MK1.

The method may include performing an etching process or the like on the via layer VIA based on the first mask MK1. Accordingly, a first contact hole HL1 corresponding to the transmission portion TP may be formed in the first pixel area PA1 of the via layer VIA. A second contact hole HL2 corresponding to the transmission portion TP may be formed in the second pixel area PA2 of the via layer VIA. A third contact hole HL3 corresponding to the transmission portion TP may be formed in the third pixel area PA3 of the via layer VIA.

The first contact hole HL1 may extend to the third insulating layer IL3 to expose at least a portion of an upper surface of the first drain electrode DE1 of the first transistor TR1. The second contact hole HL2 may extend to the third insulating layer IL3 to expose at least a portion of an upper surface of the second drain electrode DE2 of the second transistor TR2. The third contact hole HL3 may extend to the third insulating layer IL3 to expose at least a portion of an upper surface of the third drain electrode DE3 of the third transistor TR3.

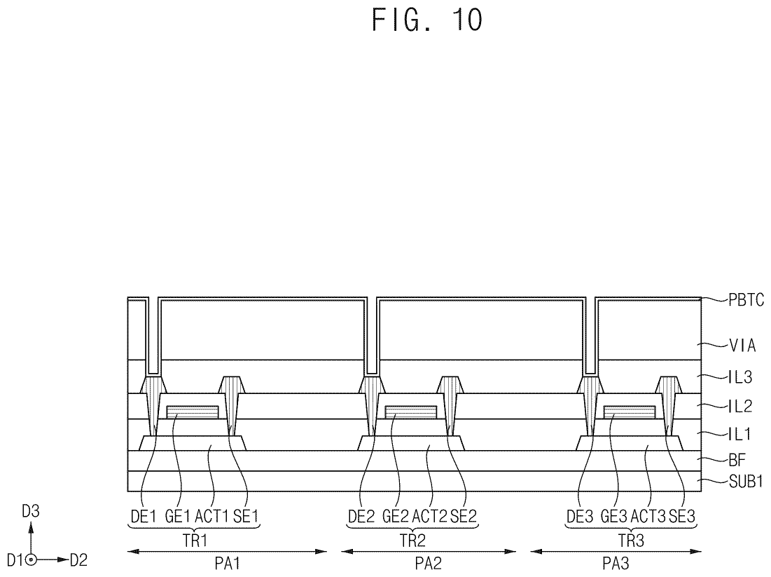

Referring further to FIG. 10, the method may include forming a preliminary lower electrode layer PBTC on the via layer VIA. The preliminary lower electrode layer PBTC may be formed continuously without a break on the via layer VIA. For example, the preliminary lower electrode layer PBTC may be formed on the via layer VIA by a sputtering method. Accordingly, the preliminary lower electrode layer PBTC may be formed on the via layer VIA with a uniform thickness. The preliminary lower electrode layer PBTC may include a same material as the first lower electrode layer (e.g., the first lower electrode layer BTC1 of FIG. 4).

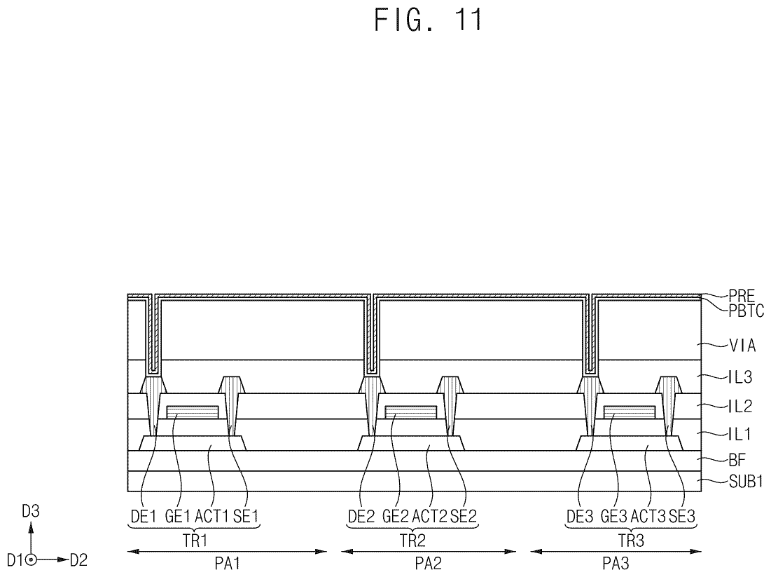

Referring further to FIG. 11, the method may include forming a preliminary reflective electrode layer PRE on the preliminary lower electrode layer PBTC. The preliminary reflective electrode layer PRE may be formed continuously without a break on the preliminary lower electrode layer PBTC. For example, the preliminary reflective electrode layer PRE may be formed on the preliminary lower electrode layer PBTC by a sputtering method. Accordingly, the preliminary reflective electrode layer PRE may be formed with a uniform thickness on the preliminary lower electrode layer PBTC. The preliminary reflective electrode layer PRE may include a same material as the first reflective electrode layer (e.g., the first reflective electrode layer RE1 of FIG. 4).

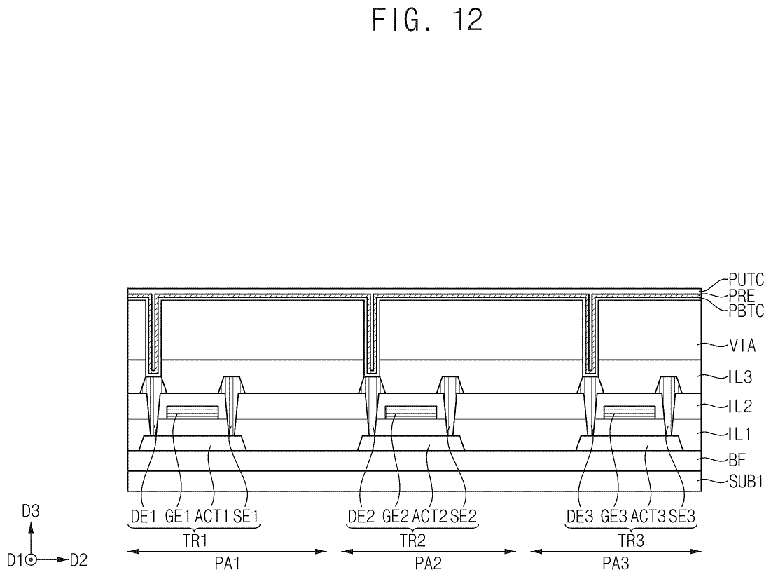

Referring further to FIG. 12, the method may include forming a preliminary upper electrode layer PUTC on the preliminary reflective electrode layer PRE. The preliminary upper electrode layer PUTC may be formed on the preliminary reflective electrode layer PRE by a sputtering method. The preliminary upper electrode layer PUTC may include a same material as the preliminary lower electrode layer PBTC. In another example, the preliminary upper electrode layer PUTC may further include a different material from a material included in the preliminary lower electrode layer PBTC.

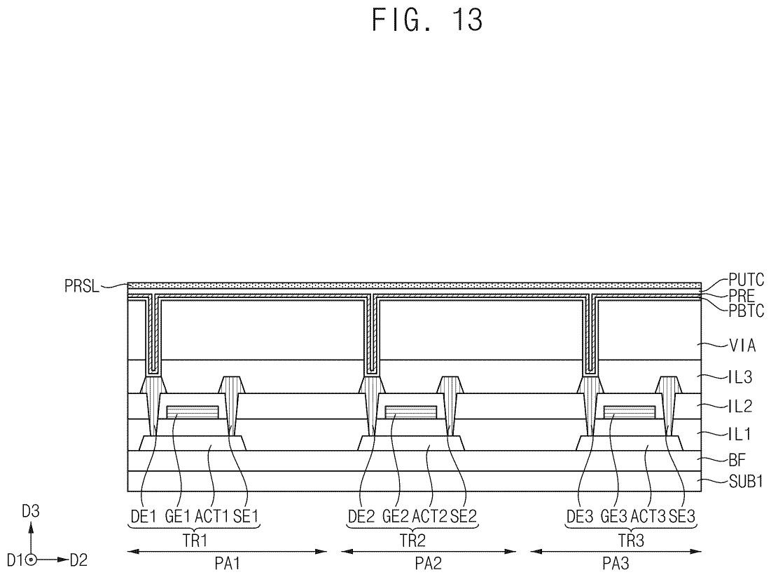

Referring further to FIG. 13, the method may include forming a preliminary resonant layer PRSL on the preliminary upper electrode layer PUTC. The preliminary resonant layer PRSL may be formed continuously without a break on the preliminary upper electrode layer PUTC. The preliminary resonant layer PRSL may be formed on the preliminary upper electrode layer PUTC by a sputtering method. Accordingly, the preliminary resonant layer PRSL may be formed with a uniform thickness on the preliminary upper electrode layer PUTC. The preliminary resonant layer PRSL may include a same material as the first resonant layer (e.g., the first resonant layer RSL1 of FIG. 4).

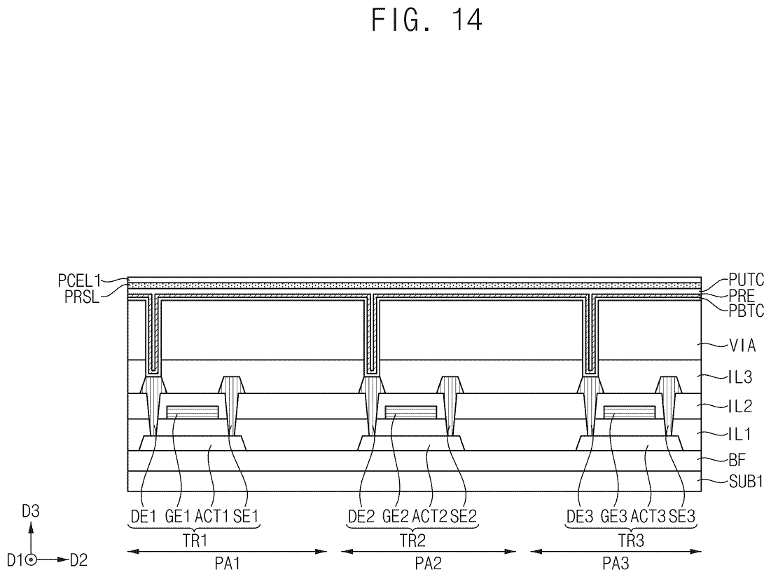

Referring further to FIG. 14, the method may include forming a first preliminary conductive layer PCEL1 on the preliminary resonant layer PRSL. The first preliminary conductive layer PCEL1 may be formed continuously without a break on the preliminary resonant layer PRSL. The first preliminary conductive layer PCEL1 may be formed on the preliminary resonant layer PRSL by a sputtering method. Accordingly, the first preliminary conductive layer PCEL1 may be formed with a uniform thickness on the preliminary resonant layer PRSL. The first preliminary conductive layer PCEL1 may include a same material as the first conductive layer (e.g., the first conductive layer CELL of FIG. 4).

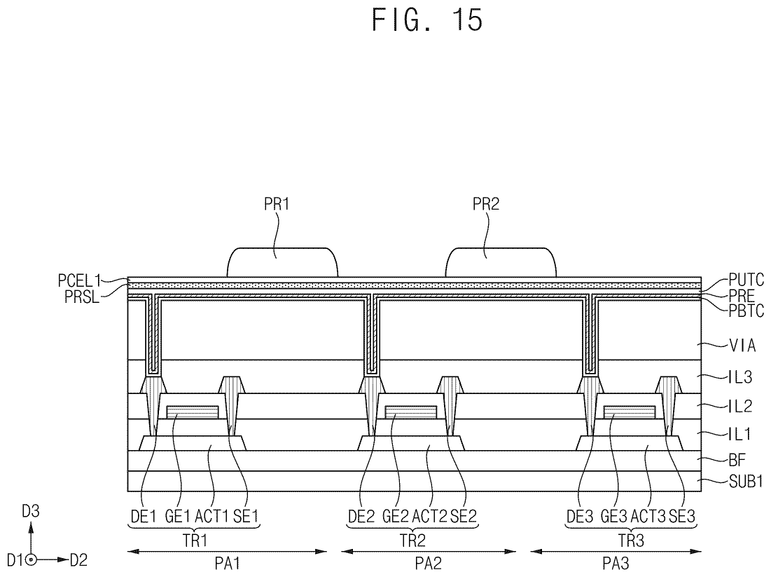

Referring further to FIG. 15, the method may include forming first and second photoresists PR1, PR2 on the first preliminary conductive layer PCEL. Specifically, the first photoresist PR1 may overlap at least a portion of the first pixel area PA1, and the second photoresist PR2 may overlap at least a portion of the second pixel area PA2. The first and second photoresists PR1, PR2 may include a same material. The first and second photoresists PR1, PR2 may each be a positive photoresist or a negative photoresist. In an embodiment, a height of an upper surface of each of the first photoresist PR1 and a height of the second photoresist PR2 may be the same with respect to the first substrate SUB1. That is, each of the first photoresist PR1 and the second photoresist PR2 may be formed in substantially the same amount on the first preliminary conductive layer PCEL.

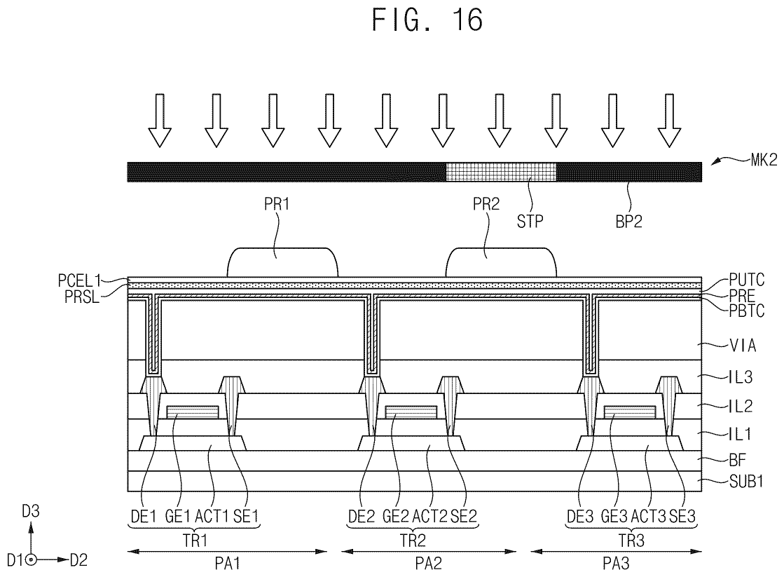

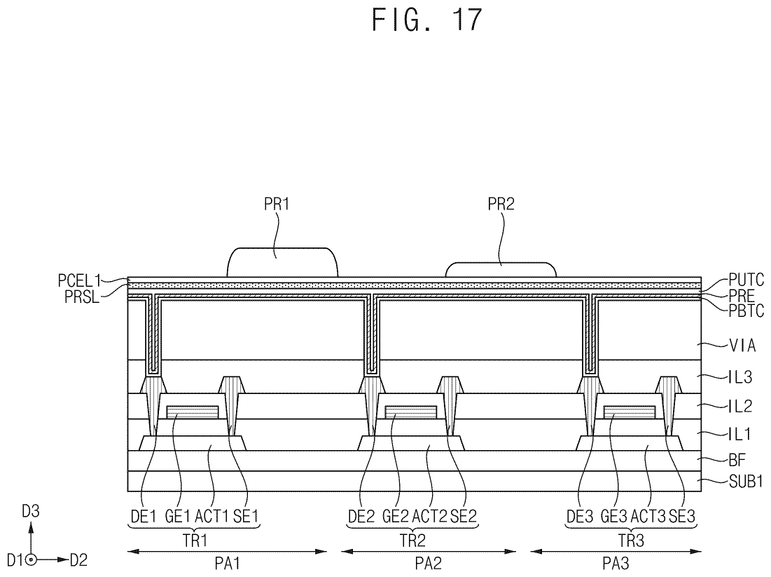

Referring further to FIGS. 16 and 17, the method may include disposing a second mask MK2 on the first and second photoresists PR1, PR2. A semi-transparent portion STP that overlaps with the second photoresist PR2 in a plan view and a second light-shielding portion BP2 may be defined on the second mask MK2.

The method may include performing an etching process or the like on the second photoresist PR2 corresponding to the semi-transparent portion STP of the second mask MK2. In some aspects, the second mask MK2 may be a halftone mask. Based on performing the etching process, a portion of the second photoresist PR2 may be removed. Accordingly, as illustrated in FIG. 17, a height of an upper surface of the second photoresist PR2 may be lower than a height of an upper surface of the first photoresist PR1 with respect to the first substrate SUB1.

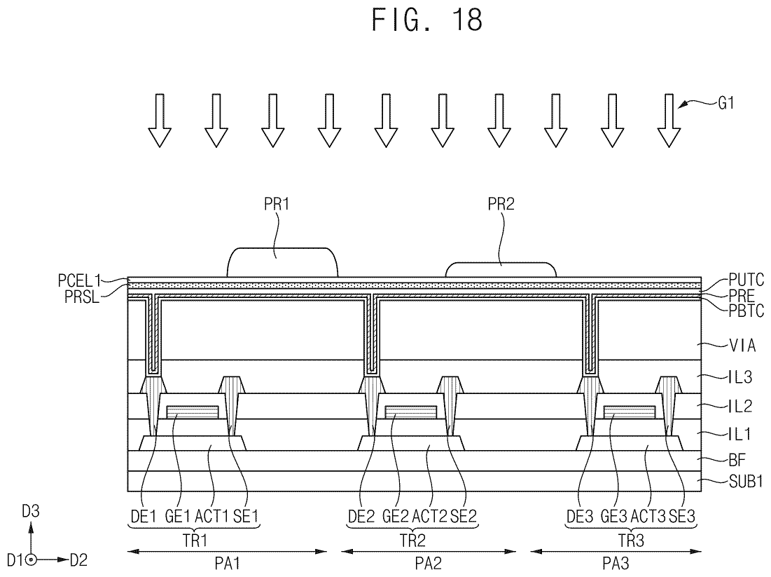

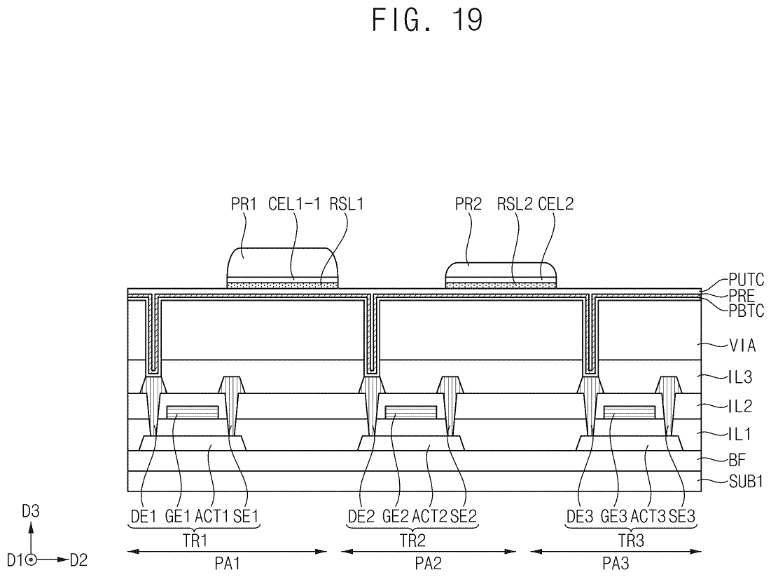

Referring further to FIGS. 18 and 19, the method may include performing a first etching process on an upper surface of the first preliminary conductive layer PCEL. In the first etching process, the first and second photoresists PR1, PR2, the first preliminary conductive layer PCEL, and the preliminary resonant layer PRSL may be etched. Specifically, since the first photoresist PR1 and the second photoresist PR2 are formed on the first preliminary conductive layer PCEL, the first preliminary conductive layer PCEL1 and the preliminary resonant layer PRSL that do not overlap with the first photoresist PR1 and the second photoresist PR2 in a plan view may be etched in the first etching process.

After the first etching process is performed, as illustrated in FIG. 19, the method may include etching the first preliminary conductive layer PCEL1 and the preliminary resonant layer PRSL, which do not overlap in a plan view with the first photoresist PR1 and the second photoresist PR2, thereby exposing an upper surface of the preliminary upper electrode layer PUTC.

In an embodiment, the first etching process may be performed using a first gas G1. For example, the first gas G1 may include hydrogen chloride (HCl). As the first etching process is performed using the first gas G1 including hydrogen chloride (HCl), the first preliminary conductive layer PCEL1 and the preliminary resonant layer PRSL may be etched. In the first etching process, the preliminary upper electrode layer may also be partially etched, but an etching process time may be controlled such that an upper surface of the preliminary reflective electrode layer is not exposed.

As the first preliminary conductive layer PCEL1 and the preliminary resonant layer PRSL are etched in the first etching process, the method may include forming each of the first preliminary conductive layer PCEL1 and the preliminary resonant layer PRSL in the first pixel area PA1 as the first-first conductive layer CEL1-1 and the first resonant layer RSL1. In some aspects, each of the first preliminary conductive layer PCEL1 and the preliminary resonant layer PRSL in the second pixel area PA2 may be formed as the second conductive layer CEL2 and the second resonant layer RSL2.

In an embodiment, a value of the etching selectivity of the first preliminary conductive layer PCEL1 with respect to the first gas G1 may range from about 50 to about 70. Preferably, a value of the etching selectivity of the first preliminary conductive layer PCEL1 with respect to the first gas G1 may range from about 55 to about 65.

In an embodiment, a value of the etching selectivity of the preliminary resonant layer PRSL with respect to the first gas G1 may range from about 20 to about 40. Preferably, a value of the etching selectivity of the preliminary resonant layer PRSL with respect to the first gas G1 may range from about 25 to about 35.

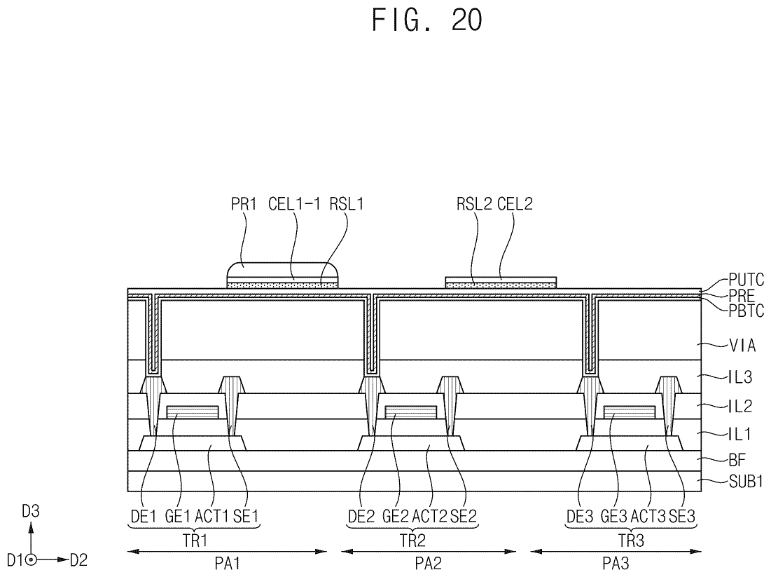

Referring further to FIG. 20, after the first etching process is performed, the method may include removing the second photoresist PR2 through a first ashing process. Specifically, through the first ashing process, a portion of the first photoresist PR1 may be removed and the entirety of the second photoresist PR2 may be removed. Accordingly, an upper surface of the second conductive layer CEL2 that overlapped the second photoresist PR2 in a plan view may be exposed.

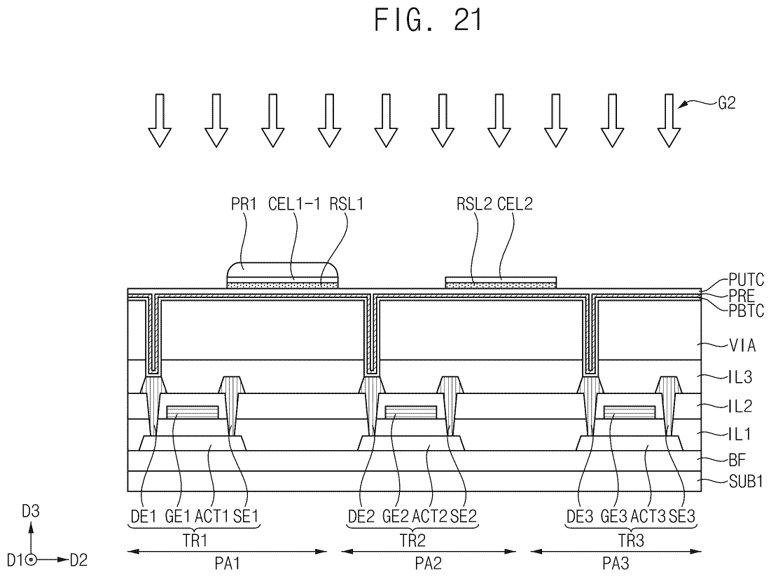

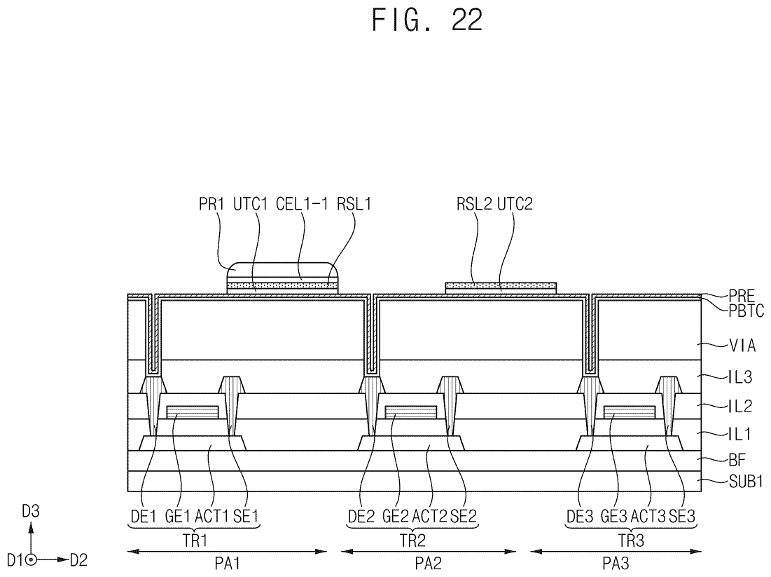

Referring further to FIGS. 21 and 22, the method may include performing a second etching process on an upper surface of the preliminary upper electrode layer PUTC. In the second etching process, the first photoresist PR1, the second conductive layer CEL2, and the preliminary upper electrode layer PUTC may be etched. Specifically, since the first photoresist PR1 is formed on the first resonant layer RSL1, the second conductive layer CEL2 and the preliminary upper electrode layer PUTC that do not overlap the first photoresist PR1 in a plan view may be etched.

After the second etching process is performed, as illustrated in FIG. 22, the method may include etching the second conductive layer CEL2 and the preliminary upper electrode layer PUTC that do not overlap the first photoresist PR1 in a plan view, such that an upper surface of the second resonant layer RSL2 and the preliminary reflective electrode layer PRE may be exposed.

In an embodiment, the second etching process may be performed using a second gas G2. For example, the second gas G2 may include acetone (CH₃COCH₃), argon (Ar), and oxygen (O). As the second etching process is performed using the second gas G2 including acetone (CH₃COCH₃), argon (Ar), and oxygen (O), the second conductive layer CEL2 and the preliminary upper electrode layer PUTC may be etched.

A value of the etching selectivity of the first preliminary conductive layer PCEL1 with respect to the second gas G2 may range from about 15 to about 30. Preferably, a value of the etching selectivity of the first preliminary conductive layer PCEL1 with respect to the second gas G2 may range from about 20 to about 25.

A value of the etching selectivity of the second resonant layer RSL2 with respect to the second gas G2 may be less than about 10. Preferably, a value of the etching selectivity of the preliminary resonant layer PRSL with respect to the second gas G2 may be less than about 5.

Since a value of the etching selectivity of the second resonant layer RSL2 with respect to the second gas G2 is significantly less than a value of the etching selectivity of the first preliminary conductive layer PCEL1 with respect to the second gas G2, as illustrated in FIG. 22, even if the second etching process is performed using the second gas G2, at least a portion of the second resonant layer RSL2 may remain. That is, in the second etching process, the second conductive layer CEL2 may be etched, but the second resonant layer RSL2 may not be etched at all.

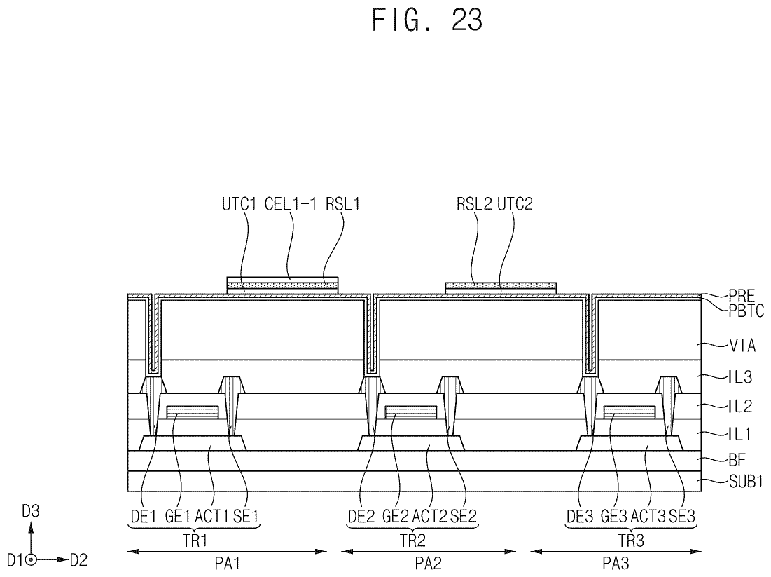

Referring further to FIG. 23, after the second etching process is performed, the method may include removing the first photoresist PR1 through a second ashing process. Specifically, through the second ashing process, an entirety of the first photoresist PR1 may be removed to expose an upper surface of the first conductive layer CELL.

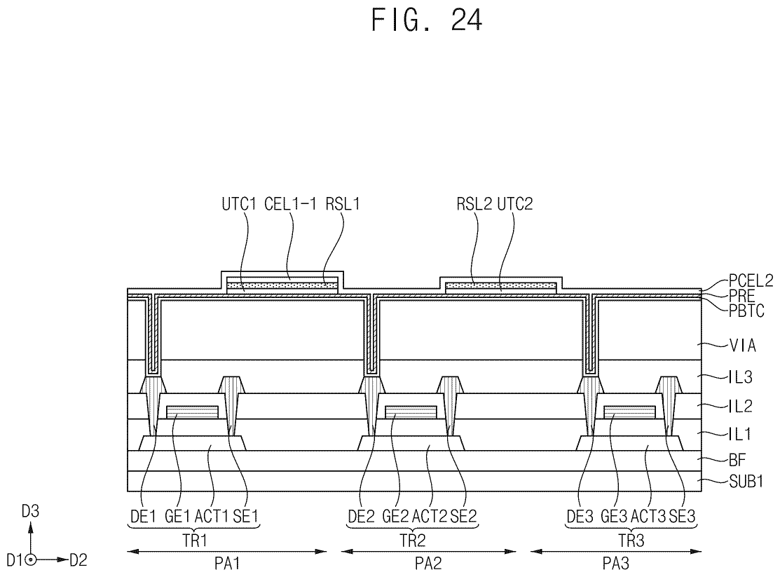

Referring further to FIG. 24, the method may include forming the second preliminary conductive layer PCEL2 on the preliminary reflective electrode layer PRE. That is, the second preliminary conductive layer PCEL2 may be applied without a break on the first substrate SUB1. Accordingly, the second preliminary conductive layer PCEL2 may be continuously formed not only on the preliminary reflective electrode layer PRE, but also on the first-first conductive layer CEL1-1 and the second resonant layer RSL2.

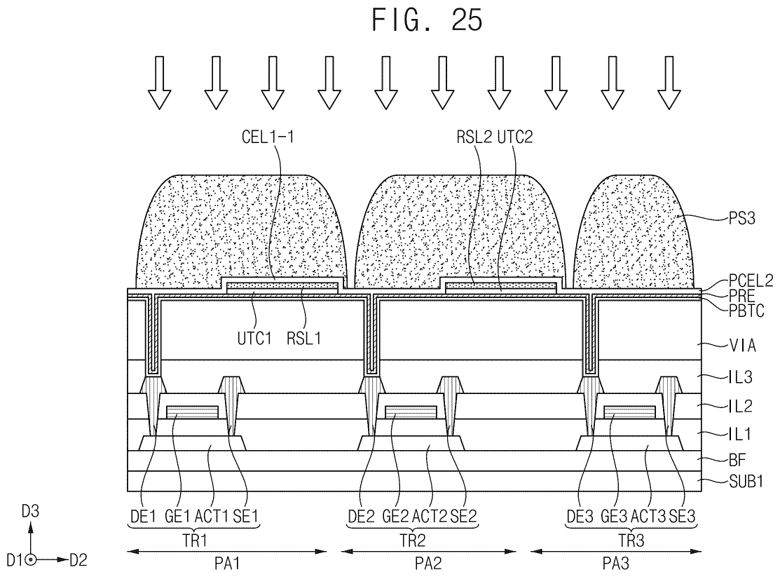

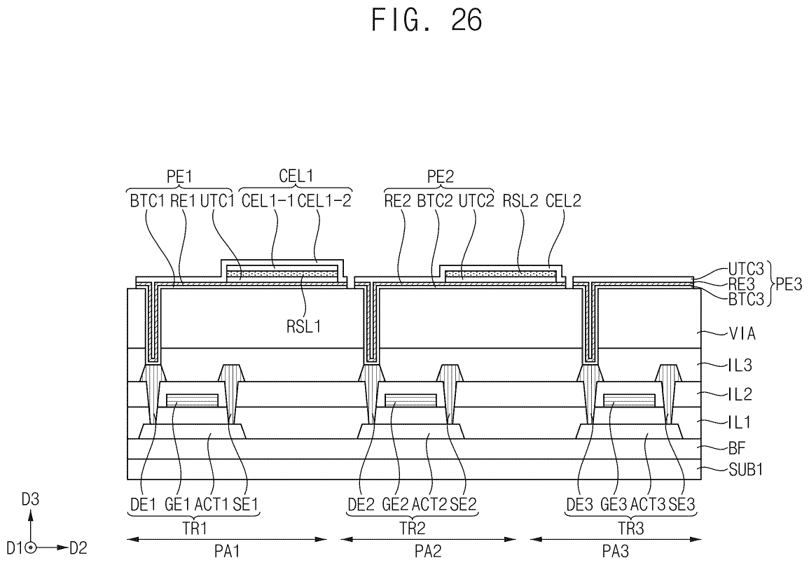

Referring further to FIGS. 25 and 26, the method may include forming third photoresists PR3 in each of the first, second, and third pixel areas PA1, PA2, and PA3. The third photoresists PR3 may be formed with predetermined interval in the first, second, and third pixel areas PA1, PA2, and PA3.

Thereafter, the method may include performing an exposure process, an etching process, or the like on the third photoresists PR3. Based on performing the etching process, a portion of the second preliminary conductive layer PCEL2, the preliminary reflective electrode layer PRE, and the preliminary lower electrode layer PBTC that does not overlap with the third photoresists PR3 in a plan view may be etched.

As the second preliminary conductive layer PCEL2, the preliminary reflective electrode layer PRE, and the preliminary lower electrode layer PBTC are etched, each of the second preliminary conductive layer PCEL2, the preliminary reflective electrode layer PRE, and the preliminary lower electrode layer PBTC may be formed as separate configurations in the first, second, and third pixel areas PA1, PA2, and PA3. The terms “etching” and “patterning” may be used interchangeably herein.

For example, as illustrated in FIG. 26, the second preliminary conductive layer PCEL2 may be formed as the first-second conductive layer CEL1-2 in the first pixel area PA1, as the second conductive layer CEL2 in the second pixel area PA2, and as the third upper electrode layer UTC3 in the third pixel area PA3. The first-first conductive layer CEL1-1 and the first-second conductive layer CEL1-2 may constitute the first conductive layer CEL1.

The preliminary reflective electrode layer PRE may be formed as the first reflective electrode layer RE1 in the first pixel area PA1, as the second reflective electrode layer RE2 in the second pixel area PA2, and as the third reflective electrode layer RE3 in the third pixel area PA3.

The preliminary lower electrode layer PBTC may be formed as the first lower electrode layer BTC1 in the first pixel area PA1, as the second lower electrode layer BTC2 in the second pixel area PA2, and as the third lower electrode layer BTC3 in the third pixel area PA3.

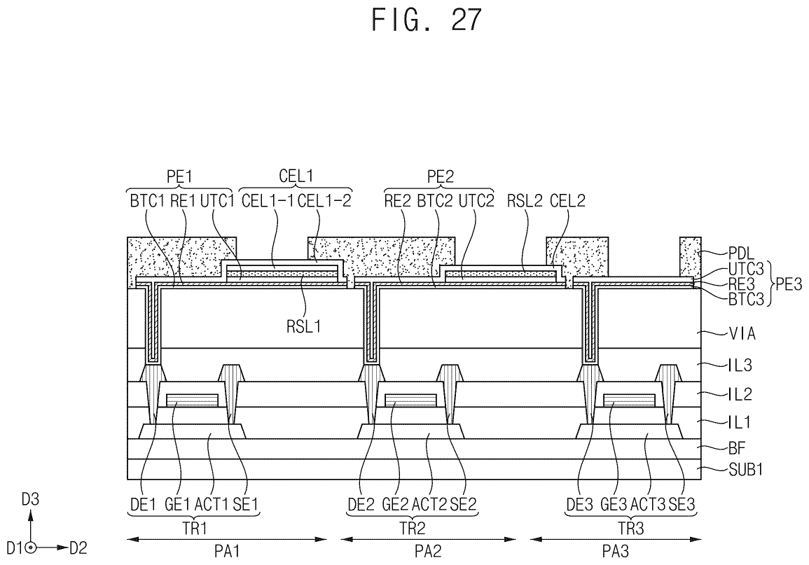

Referring further to FIG. 27, the method may include forming the pixel defining film PDL between the first pixel electrode layer PE1, the second pixel electrode layer PE2, and the third pixel electrode layer PE3. The pixel defining film PDL may be formed while covering at least a portion of each of the first pixel electrode layer PE1, the second pixel electrode layer PE2, and the third pixel electrode layer PE3. Specifically, the pixel defining film PDL may expose at least a portion of an upper surface of each of the first conductive layer CEL1, the second conductive layer CEL2, and the third upper electrode layer UTC3.

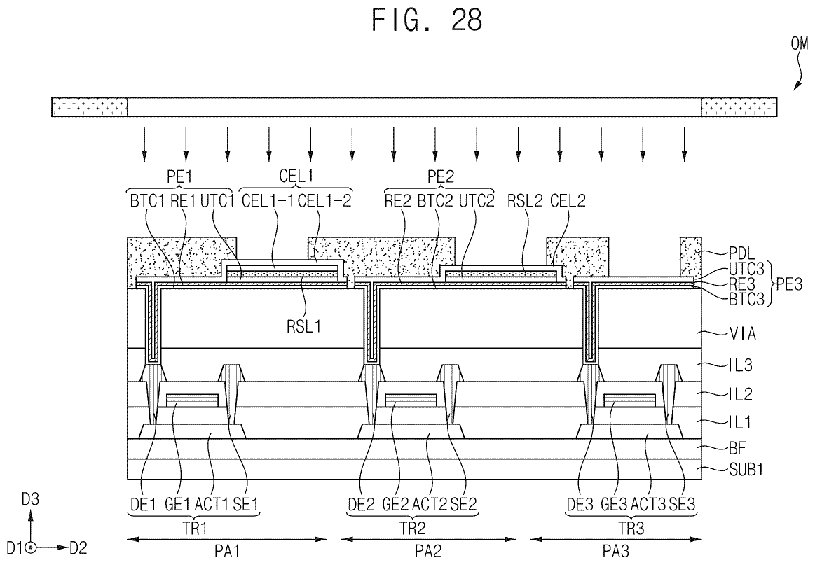

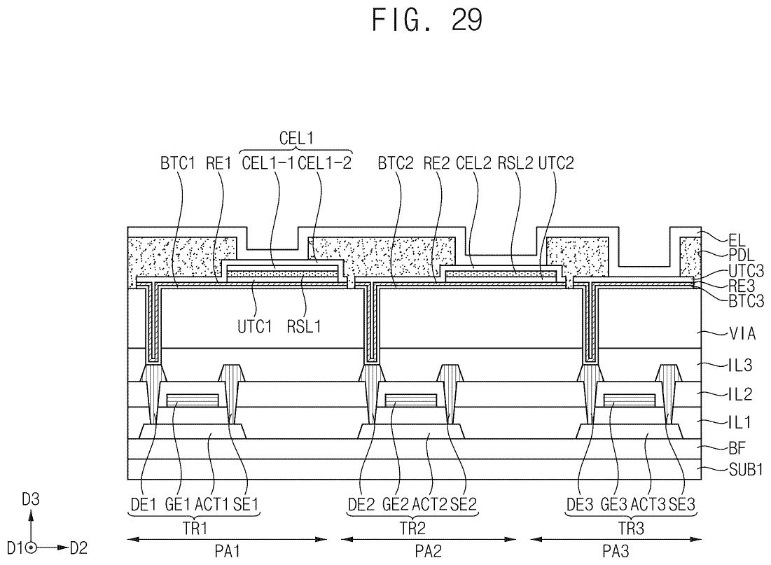

Referring further to FIGS. 28 and 29, the method may include disposing an open mask OM on the first, second, and third pixel electrode layers PE1, PE2, and PE3 and the pixel defining film PDL. The light emitting layer EL may be formed by placing the open mask OM on the first, second, and third pixel electrode layers PE1, PE2, and PE3 and the pixel defining film PDL. As the light emitting layer EL is formed by the open mask OM, the light emitting layer EL may be formed continuously on the first, second, and third pixel electrode layers PE1, PE2, and PE3, as illustrated in FIG. 29. The light emitting layer EL may be formed with a uniform thickness.

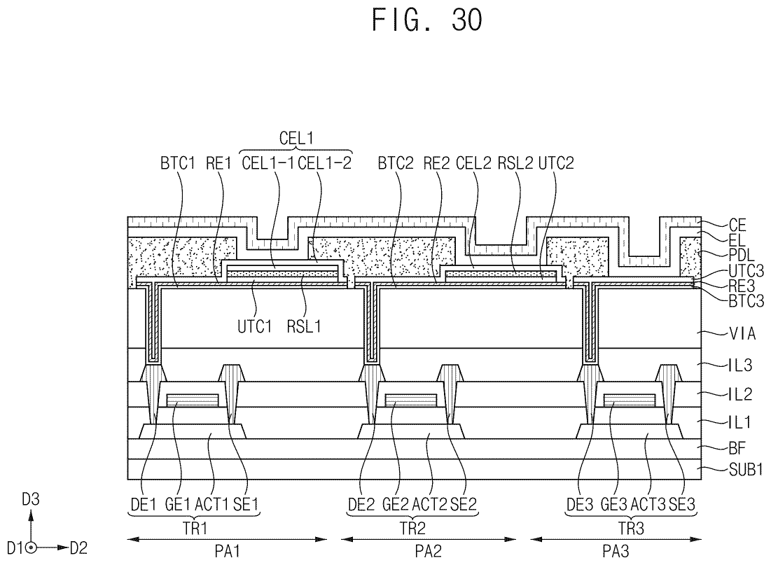

Referring further to FIG. 30, the method may include forming the common electrode CE on the light emitting layer EL. The common electrode CE may be formed continuously without a break on the light emitting layer EL. The common electrode CE may be formed with a uniform thickness on the light emitting layer EL. That is, the common electrode CE may be a plate electrode with a uniform thickness.

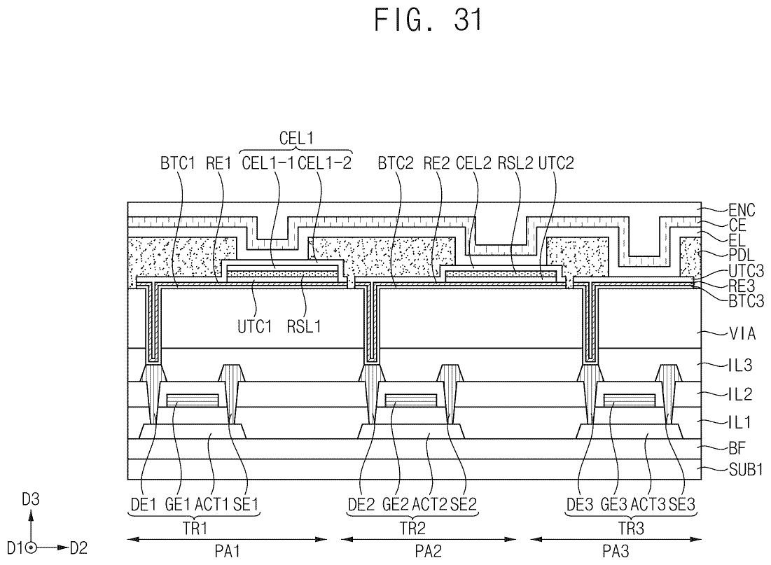

Referring further to FIG. 31, the method may include forming the encapsulation layer ENC on the common electrode CE. An upper surface of the encapsulation layer ENC may be formed flat. The encapsulation layer ENC may include at least one inorganic encapsulation layer and at least one organic encapsulation layer.

Referring further to FIG. 32, the method may include sequentially forming the first, second, and third color filters CF1, CF2, and CF3 on the second substrate SUB2.

The first color filter CF1 may be formed such that the first color filter CF1 overlaps the first pixel area PA1. The first color filter CF1 may also be formed in an area that does not overlap the second pixel area PA2 and the third pixel area PA3. The first color filter CF1 may be a red color filter that transmits red light.

The second color filter CF2 may be formed such that the second color filter CF2 overlaps the second pixel area PA2. The second color filter CF2 may be formed on at least a portion of the first color filter CF1. The second color filter CF2 may be a green color filter that transmits green light.

The third color filter CF3 may be formed such that the third color filter CF3 overlaps the third pixel area PA3. The third color filter CF3 may also be formed such that the third color filter CF3 overlaps the first color filter CF1 and/or the second color filter CF2. The third color filter CF3 may be a blue color filter that transmits blue light.

Accordingly, the first color filter CF1 may be formed in at least a portion of the first pixel area PA1 of the second substrate SUB2, without forming other color filters in at least the portion of the first pixel area PA1 of the second substrate SUB2. The second color filter CF2 may be formed in at least a portion of the second pixel area PA2 of the second substrate SUB2, without forming other color filters in at least the portion of the second pixel area PA2 of the second substrate SUB2. The third color filter CF3 may be formed in at least a portion of the third pixel area PA3 of the second substrate SUB2, without forming other color filters in at least the portion of the third pixel area PA3 of the second substrate SUB2.

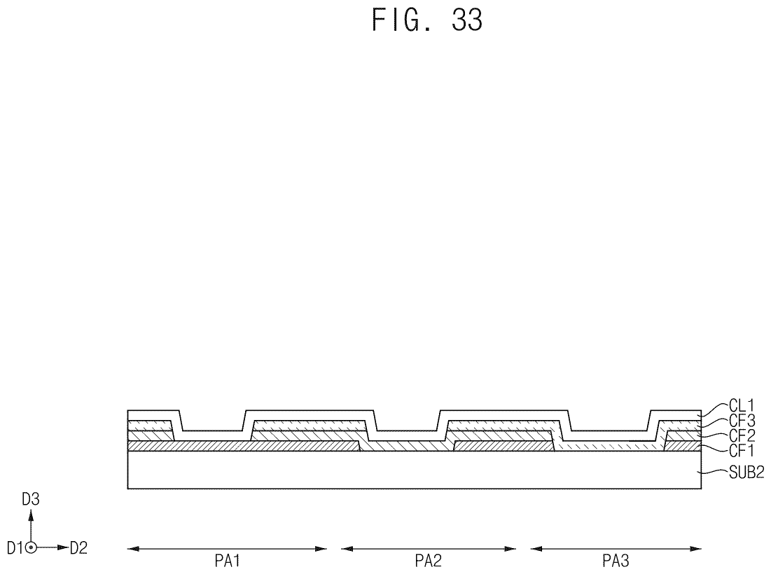

Referring further to FIG. 33, the method may include forming the first capping layer CL1 on the first color filter CF1, the second color filter CF2, and the third color filter CF3. The first capping layer CL1 may be formed continuously without a break on the first color filter CF1, the second color filter CF2, and the third color filter CF3. The first capping layer CL1 may be formed along a profile of each of the first color filter CF1, the second color filter CF2, and the third color filter CF3.

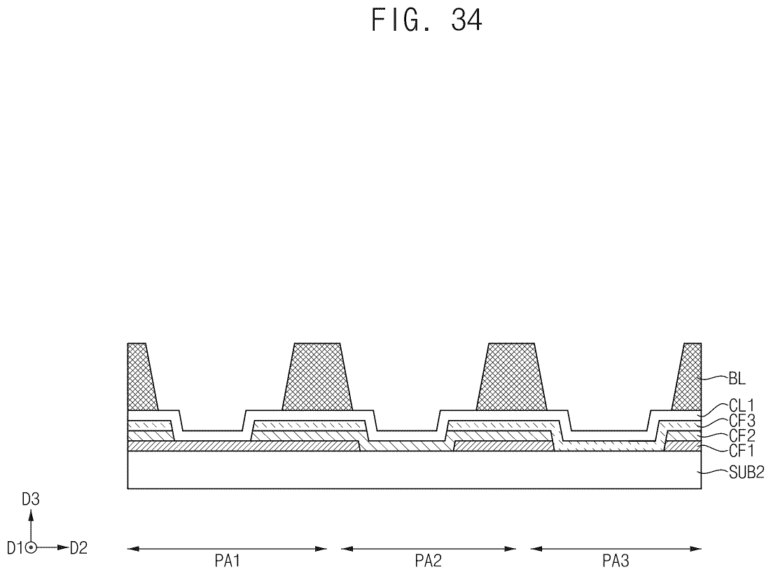

Referring further to FIG. 34, the method may include forming the light blocking member BL between the first pixel area PA1, the second pixel area PA2, and the third pixel area PA3.

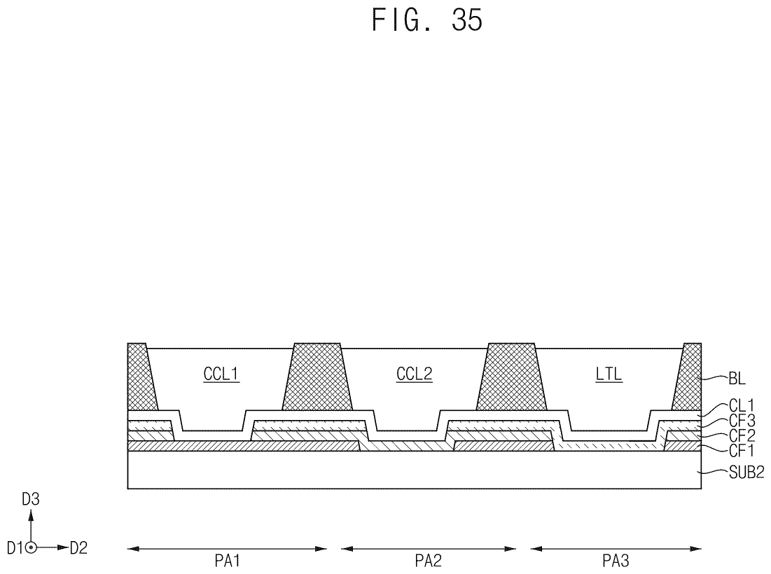

Referring further to FIG. 35, the method may include forming the first color conversion layer CCL1 in an opening defined by the light blocking member BL and overlapping the first pixel area PA1. The second color conversion layer CCL2 may be formed in an opening defined by the light blocking member BL and overlapping the second pixel area PA2. The light transmitting layer LTL may be formed in an opening defined by the light blocking member BL and overlapping the third pixel area PA3.

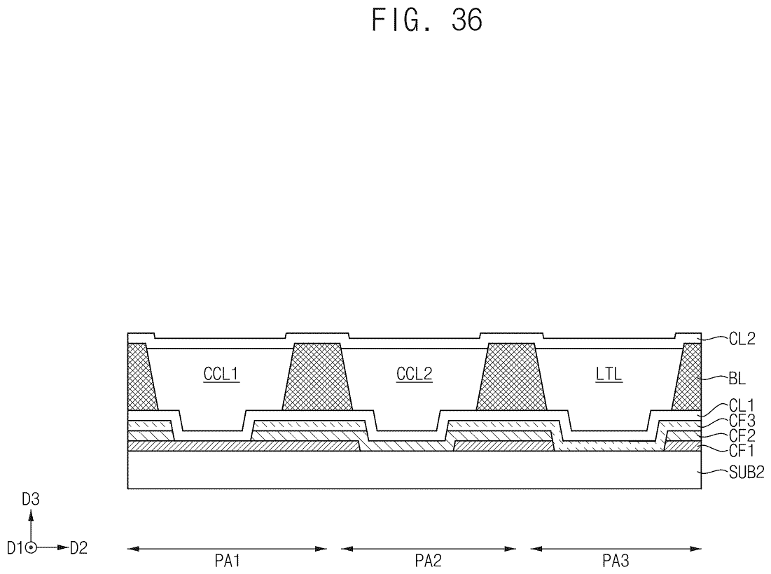

Referring further to FIG. 36, the method may include forming the second capping layer CL2 on the first color conversion layer CCL1, the second color conversion layer CCL2, the light transmitting layer LTL, and the light blocking member BL. The second capping layer CL2 may cover the light blocking member BL, the first color conversion layer CCL1, the second color conversion layer CCL2, and the light transmitting layer LTL. For example, the second capping layer CL2 may be formed using an inorganic material.

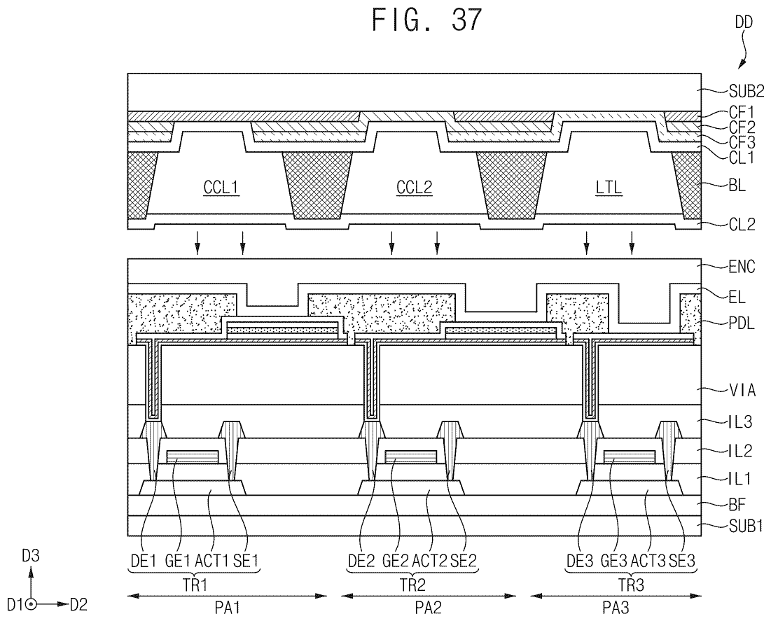

Referring further to FIG. 37, the encapsulating layer ENC and the second capping layer CL2 may be combined through the filling layer (e.g., the filling layer FL of FIG. 3). As a result, the display device DD of FIG. 3 including the first substrate SUB1 and the second substrate SUB2 facing the first substrate SUB1 may be formed.

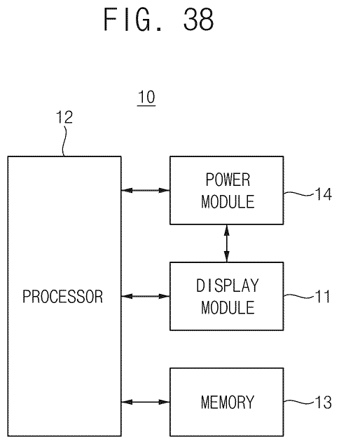

FIG. 38 is a block-diagram illustrating an electronic device according to an embodiment of the present disclosure.

Referring to FIGS. 1 and 38, the display device DD according to the embodiments may be applied to various electronic devices 10. The electronic device 10 according to an embodiment includes the display device DD described herein, and may further include a module or device having additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The processor 12 may drive the display device DD.

The memory 13 may store data information for the operation of the processor 12 or the display module 11. In an example in which the processor 12 executes an application stored in the memory 13, an image data signal and/or an input control signal may be transmitted to the display module 11, and the display module 11 may process the received signal and output image information through a display screen.

The power module 14 may include a power supply module such as, for example, a power adapter or a battery device and the power supplied by the power supply module. Specifically, the power module 14 may include a power conversion module that generates power for the operation of the electronic device 10.

At least one of the components of the electronic device 10 described herein may be included in the display device according to the embodiments described herein. In some aspects, some of the individual modules functionally included in one module may be included in the display device, and others may be provided separately from the display device. For example, the display device DD may include the display module 11, and the processor 12, the memory 13, and the power module 14 may be provided in the form of other devices within the electronic device 10 other than the display device DD.

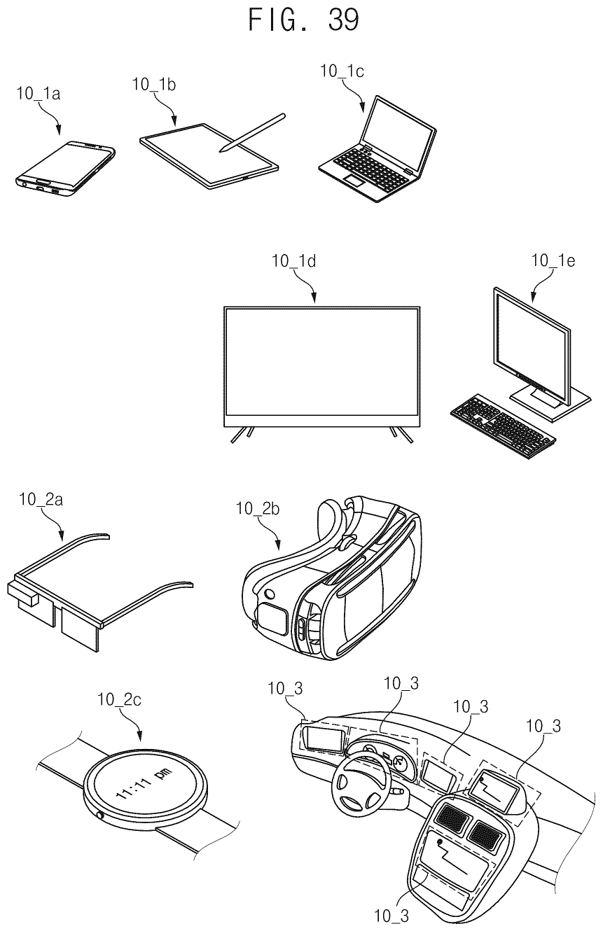

FIG. 39 is a schematic view of the electronic device according to various embodiments of FIG. 38.

Referring to FIGS. 38 and 39, various electronic devices 10 to which the display device DD according to the embodiments may be applied may include electronic devices for displaying images, such as, for example, a smart phone 10_1a, a tablet PC 10_1b, a laptop 10_1c, a TV 10_1d, and a desk monitor 10_1e. In some aspects, the electronic devices 10 may include wearable electronic devices including display modules such as, for example, smart glasses 10_2a, head mounted displays 10_2b, smart watches 10_2c, and vehicle electronic devices 10_3 including display modules such as, for example, CID (Center Information Display) and room mirror displays disposed on the instrument panel, center fascia, and dashboard of a car. However, this is an example, and the electronic device 10 according to embodiments of the present disclosure is not necessarily limited thereto. For example, the electronic device 10 may be implemented as a mobile phone, a video phone, a smart pad, a smart watch, a tablet PC, a vehicle display, a computer monitor, a notebook, a head mounted display device, or the like. In some aspects, the electronic device 10 may be a television, a monitor, a notebook computer, or a tablet. In some aspects, the electronic device 10 may be a car.

What is claimed is:

1. A display device comprising:
a substrate comprising a first pixel area and a second pixel area adjacent to the first pixel area;
a first pixel electrode layer disposed in the first pixel area on the substrate;
a second pixel electrode layer disposed in the second pixel area on the substrate;
a first resonant layer disposed on the first pixel electrode layer and comprising an inorganic material;
a second resonant layer disposed on the second pixel electrode layer and comprising the inorganic material;
a first conductive layer disposed on the first resonant layer;
a second conductive layer disposed on the second resonant layer, wherein a height of an upper surface of the second conductive layer is different from a height of an upper surface of the first conductive layer with respect to the substrate; and
a light emitting layer disposed on the first conductive layer and the second conductive layer.

2. The display device of claim 1, wherein each of the first resonant layer and the second resonant layer comprises at least one selected from a group comprising silicon nitride and silicon oxide.

3. The display device of claim 2, wherein a thickness of the first resonant layer and a thickness of the second resonant layer are equal to one another.

4. The display device of claim 1, wherein each of the first resonant layer and the second resonant layer comprises a transparent material.

5. The display device of claim 1, wherein:
the first pixel electrode layer comprises a first lower electrode layer, a first reflective electrode layer, and a first upper electrode layer sequentially disposed on the substrate, and
the second pixel electrode layer comprises a second lower electrode layer, a second reflective electrode layer, and a second upper electrode layer sequentially disposed on the substrate.

6. The display device of claim 5, wherein:
the first upper electrode layer of the first pixel electrode layer is electrically connected to the first conductive layer, and
the second upper electrode layer of the second pixel electrode layer is electrically connected to the second conductive layer.

7. The display device of claim 5, wherein the first lower electrode layer, the first upper electrode layer, and the first conductive layer comprise a same material.

8. The display device of claim 1, wherein a height of an upper surface of the first pixel electrode layer and a height of an upper surface of the second pixel electrode layer are equal with respect to the substrate.

9. The display device of claim 1, wherein a thickness of the first pixel electrode layer and a thickness of the second pixel electrode layer are different from each other.

10. The display device of claim 1, the light emitting layer comprises a light emitting material that emits white light or blue light.

11. The display device of claim 1, further comprising:
a common electrode disposed on the light emitting layer, wherein the common electrode is a plate electrode.

12. The display device of claim 11, further comprising:
a first color conversion layer disposed on the common electrode, overlapping the first pixel electrode layer in a plan view, and converting light emitted from the light emitting layer into light of a first color; and
a second color conversion layer disposed on the common electrode, overlapping the second pixel electrode layer in a plan view, and converting the light emitted from the light emitting layer into light of a second color different from the first color.

13. The display device of claim 12, wherein a resonance distance between the common electrode and a first reflective electrode layer comprised in the first pixel electrode layer satisfies a following Equation 1:
L=(λ/2)×N,
wherein L is the resonance distance, λ is a median value of a wavelength of the first color, and N is a natural number.

14. The display device of claim 1, wherein:
the substrate further comprises a third pixel area adjacent to the second pixel area; and
the display device further comprises a third pixel electrode layer disposed in the third pixel area on the substrate.

15. The display device of claim 14, wherein:
the third pixel electrode layer comprises a third lower electrode layer, a third reflective electrode layer, and a third upper electrode layer sequentially disposed on the substrate, and
the third upper electrode layer is in direct contact with the light emitting layer.

16. A method of manufacturing a display device comprising:
forming a preliminary lower electrode layer, a preliminary reflective electrode layer, a preliminary upper electrode layer, a preliminary resonant layer, and a first preliminary conductive layer sequentially on a substrate comprising a first pixel area and a second pixel area adjacent to the first pixel area;
forming a first photoresist in the first pixel area on the first preliminary conductive layer;
forming a second photoresist in the second pixel area on the first preliminary conductive layer, wherein the second photoresist has an upper surface at a same height as an upper surface of the first photoresist with respect to an upper surface of the substrate;
removing a portion of the second photoresist using a halftone mask;
etching the first preliminary conductive layer and the preliminary resonant layer through a first etching process;
removing the second photoresist;
etching the first preliminary conductive layer and the preliminary upper electrode layer through a second etching process; and
forming a first pixel electrode layer, a first resonant layer, and a first conductive layer in the first pixel area and at a same time forming a second pixel electrode layer, a second resonant layer, and a second conductive layer in the second pixel area, by patterning the preliminary lower electrode layer, the preliminary reflective electrode layer, and the preliminary upper electrode layer.

17. The method of claim 16, wherein the first etching process is performed using a first gas comprising hydrogen chloride (HCl).

18. The method of claim 16, wherein:
the second etching process is performed using a second gas comprising acetone (CH₃COCH₃), argon (Ar), and oxygen (O), and
in the second etching process, an etching selectivity of the first preliminary conductive layer with respect to the second gas is greater than an etching selectivity of the preliminary resonant layer with respect to the second gas.

19. The method of claim 16, further comprising:
forming a light emitting layer using an open mask on the first pixel electrode layer and the second pixel electrode layer.

20. An electronic device comprising:
a display device; and
a processor configured to drive the display device,
wherein the display device comprises:
a substrate comprising a first pixel area and a second pixel area adjacent to the first pixel area;
a first pixel electrode layer disposed in the first pixel area on the substrate;
a second pixel electrode layer disposed in the second pixel area on the substrate;
a first resonant layer disposed on the first pixel electrode layer and comprising an inorganic material;
a second resonant layer disposed on the second pixel electrode layer and comprising the inorganic material;
a first conductive layer disposed on the first resonant layer;
a second conductive layer disposed on the second resonant layer, wherein a height of an upper surface of the second conductive layer is different from a height of an upper surface of the first conductive layer with respect to the substrate; and
a light emitting layer disposed on the first conductive layer and the second conductive layer.
